(19) United States
(12) Patent Application Publication
(10) Pub. No.: US 2026/0190491 A1
(43) Pub. Date: Jul. 2, 2026

(54) SEMICONDUCTOR DEVICE, METHOD FOR MANUFACTURING SEMICONDUCTOR DEVICE, DISPLAY DEVICE, AND METHOD FOR MANUFACTURING DISPLAY DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Masahiro WATABE, Tokyo (JP)

(73) Assignee: Japan Display Inc., Tokyo (JP)

(21) Appl. No.: 19/549,016

(22) Filed: Feb. 25, 2026

Related U.S. Application Data
(63) Continuation of application No. PCT/JP2024/027788, filed on Aug. 2, 2024.

(30) Foreign Application Priority Data
Aug. 30, 2023 (JP) 2023-140464

(51) Int. Cl. H10D 86/40; H10D 86/01; H10D 86/60

(52) U.S. Cl. CPC H10D 86/451; H10D 86/0231; H10D 86/423; H10D 86/60

(57) ABSTRACT

A semiconductor device includes an oxide semiconductor layer, a gate electrode opposed to the oxide semiconductor layer, a gate insulating layer between the oxide semiconductor layer and the gate electrode, a first conductive layer connected to the oxide semiconductor layer, a first transparent conductive layer arranged on a layer above the first conductive layer and connected to the oxide semiconductor layer, and a first insulating layer containing silicon nitride arranged on and in contact with the oxide semiconductor layer.

### CROSS-REFERENCE TO RELATED APPLICATIONS

This application is a Continuation of International Patent Application No. PCT/JP2024/027788, filed on Aug. 2, 2024, which claims the benefit of priority to Japanese Patent Application No. 2023-140464, filed on Aug. 30, 2023, the entire contents of each are incorporated herein by reference.

### FIELD

An embodiment of the present invention relates to a semiconductor device including an oxide semiconductor layer and a method for manufacturing the oxide semiconductor. Further, an embodiment of the present invention relates to a display device including the semiconductor device and a method for manufacturing the display device.

### BACKGROUND

In recent years, in place of amorphous silicon, low-temperature polysilicon, and single-crystal silicon, a transistor using an oxide semiconductor as a channel has been developed (see, for example, Japanese Laid-Open Patent Publication No. 2014-146819 and Japanese Laid-Open Patent Publication No. 2015-159315). A transistor in which an oxide semiconductor is used as a channel is formed by a simple structure and a low-temperature process similar to a transistor in which amorphous silicon is used as a channel. It is known that a transistor using an oxide semiconductor as a channel has higher mobility and a very low off-state current compared to a transistor using amorphous silicon as a channel.

### SUMMARY

A semiconductor device according to an embodiment of the present invention includes an oxide semiconductor layer, a gate electrode opposed to the oxide semiconductor layer, a gate insulating layer between the oxide semiconductor layer and the gate electrode, a first conductive layer connected to the oxide semiconductor layer, a first transparent conductive layer arranged in a layer above the first conductive layer and connected to the oxide semiconductor layer, and a first insulating layer including silicon nitride arranged on and in contact with the first transparent conductive layer.

A method for manufacturing a semiconductor device according to an embodiment of the present invention includes forming an oxide semiconductor layer, forming a gate insulating layer on the oxide semiconductor layer, forming a gate electrode on the gate insulating layer, forming a first conductive layer in contact with the oxide semiconductor layer above the gate electrode, forming a first transparent conductive layer in contact with the oxide semiconductor layer above the first conductive layer, and forming a first insulating layer containing silicon nitride in contact with the first transparent conductive layer.

### BRIEF DESCRIPTION OF DRAWINGS

FIG. 1 is a cross-sectional view showing a configuration of a semiconductor device according to an embodiment of the present invention.

FIG. 2 is a plan view showing a configuration of a semiconductor device according to an embodiment of the present invention.

FIG. 3 is a sequence diagram showing a method for manufacturing a semiconductor device according to an embodiment of the present invention.

FIG. 4 is a sequence diagram showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a configuration of a semiconductor device according to an embodiment of the present invention.

FIG. 14 is a cross-sectional view showing a configuration of a semiconductor device according to an embodiment of the present invention.

FIG. 15 is a plan view showing an outline of a display device according to an embodiment of the present invention.

FIG. 16 is a block diagram showing a configuration of a display device according to an embodiment of the present invention.

FIG. 17 is a circuit diagram showing a pixel circuit of a pixel of a display device according to an embodiment of the present invention.

FIG. 18 is a cross-sectional view showing a configuration of a display device according to an embodiment of the present invention.

FIG. 19 is a plan view showing a configuration of a display device according to an embodiment of the present invention.

FIG. 20 is a plan view showing a configuration of a display device according to an embodiment of the present invention.

FIG. 21 is a cross-sectional view showing a configuration of a display device according to an embodiment of the present invention.

FIG. 22 is a cross-sectional view showing a configuration of a semiconductor device according to an embodiment.

FIG. 23 shows measurement results of the contact resistance in Conditions A to G for a fifth insulating layer.

FIG. 24 shows measurement results of the contact resistance in Conditions A to G for the fifth insulating layer.

### DESCRIPTION OF EMBODIMENTS

In the case where the semiconductor device is required to have high light transmittance, at least one of the source electrode and the drain electrode may be formed of a transparent conductive layer. For example, if a transparent conductive layer such as ITO is formed so as to be in contact with the silicon layer, the silicon layer is oxidized by a process gas and an oxygen ion at the time of ITO film formation. Since the oxide layer formed on a surface of the silicon layer has high resistance, contact resistance between the silicon layer and the transparent conductive layer increases. As a result, electrical contact between the silicon layer and the transparent conductive layer is poor.

Similarly, in the case where the ITO film is formed so as to be in contact with the oxide semiconductor layer, the oxide semiconductor layer in the low-resistance source region or the drain region is oxidized by the process gas or the oxygen ion at the time of film formation of the ITO immediately after the formation of the ITO. Even so, compared to forming the ITO film in contact with a silicon layer, although forming the ITO film in contact with an oxide semiconductor layer can reduce the contact resistance, there is a problem in that the electrical characteristics of the transistor are degraded due to the high contact resistance between the ITO film and the oxide semiconductor layer.

An object of an embodiment of the present invention is to improve the electrical characteristics of a transistor in a semiconductor device.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, film thicknesses, shapes, and the like of respective portions as compared with actual embodiments. However, the shown shapes are merely examples, and do not limit the interpretation of the present invention. In the present specification and the drawings, the same reference signs are given to the same components as those described above with respect to the drawings described above, and detailed description thereof may be omitted as appropriate.

A “semiconductor device” refers to an overall device that can function by utilizing semiconductor characteristics. The transistor and the semiconductor circuit are one form of a semiconductor device. A semiconductor device of an embodiment described below may be, for example, a transistor used in an integrated circuit (Integrated Circuit: IC) such as a display device or a microprocessor (Micro-Processing Unit: MPU) or a memory circuit.

A “display device” refers to a structure that displays an image using an electro-optical layer. For example, the term “display device” may refer to a display panel including an electro-optical layer, or may refer to a structure in which another optical member (for example, a polarizing member, a backlight, a touch panel, or the like) is attached to a display cell. An “electro-optical layer” may include a liquid crystal layer, an electroluminescent (EL) layer, an electrochromic (EC) layer, or an electrophoretic layer, unless there is a technical inconsistency. Therefore, although an embodiment to be described later will be described by exemplifying a liquid crystal display device including a liquid crystal layer and an organic EL display device including an organic EL layer as a display device, the structure of the present embodiment can be applied to a display device including another electro-optical layer described above.

In each embodiment of the present invention, a direction from the substrate toward the oxide semiconductor layer is referred to as “above” or “upper”. Conversely, a direction from the oxide semiconductor layer toward the substrate is referred to as “under” or “lower”. As described above, for convenience of explanation, although the term “upper” or “lower” is used to describe, for example, the upper and lower relationships between the substrate and the oxide semiconductor layer may be arranged in a direction different from that shown in the figure. In the following description, for example, the expression “oxide semiconductor layer above the substrate” merely describes the vertical relationship between the substrate and the oxide semiconductor layer as described above, and other members may be arranged between the substrate and the oxide semiconductor layer. The term “upper” or “lower” means a stacking order in a structure in which a plurality of layers are stacked, and in the case where the stacking order is expressed as “pixel electrode above the transistor”, the positional relationship may be such that the transistor and the pixel electrode do not overlap each other in a plan view. On the other hand, in the case where the stacking order is expressed as “pixel electrode vertically above the transistor”, this means a positional relationship in which the transistor and the pixel electrode overlap each other in a plan view.

As used herein, the phrase “a includes A, B, or C,” “a includes any of A, B, or C,” “α includes one selected from a group consisting of A, B, and C,” and the like does not exclude cases where α comprises a plurality of combinations of A to C unless otherwise indicated. Furthermore, these expressions do not exclude the case where α includes other elements.

In addition, the following embodiments can be combined with each other as long as there is no technical inconsistency.

### First Embodiment

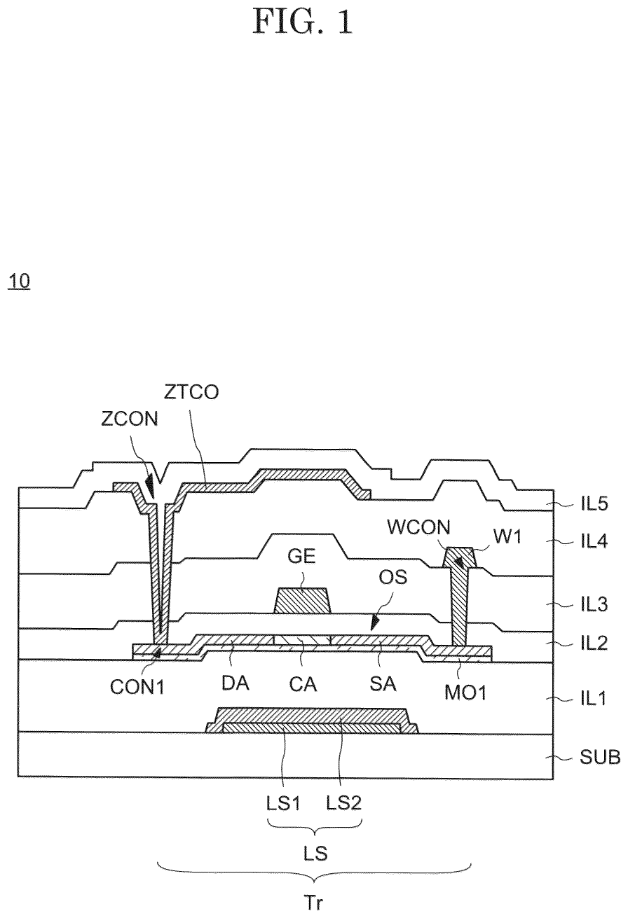

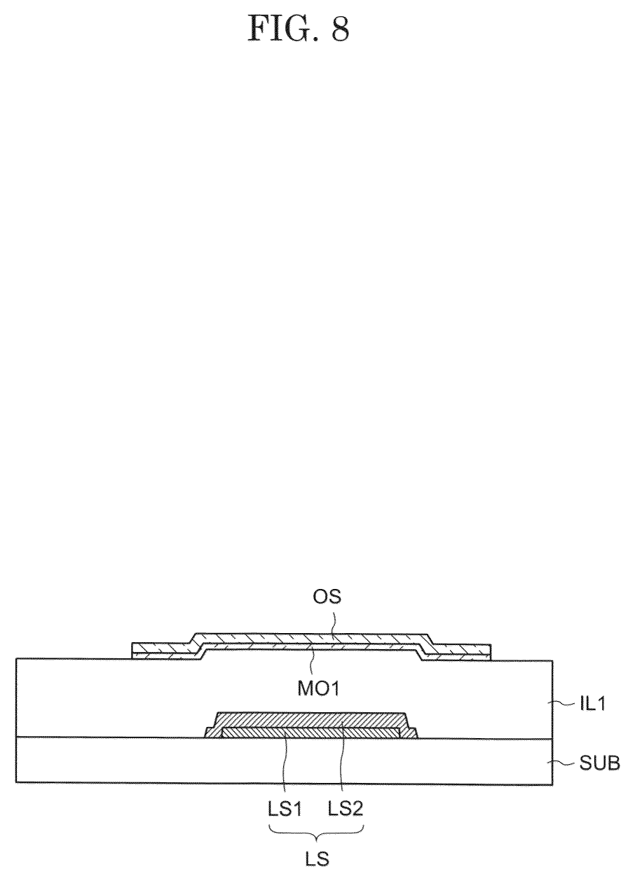

Referring to FIG. 1 to FIG. 14, semiconductor devices 10, 10A, and 10B according to an embodiment of the present disclosure will be described.

### [1.1. Configuration of Semiconductor Device 10]

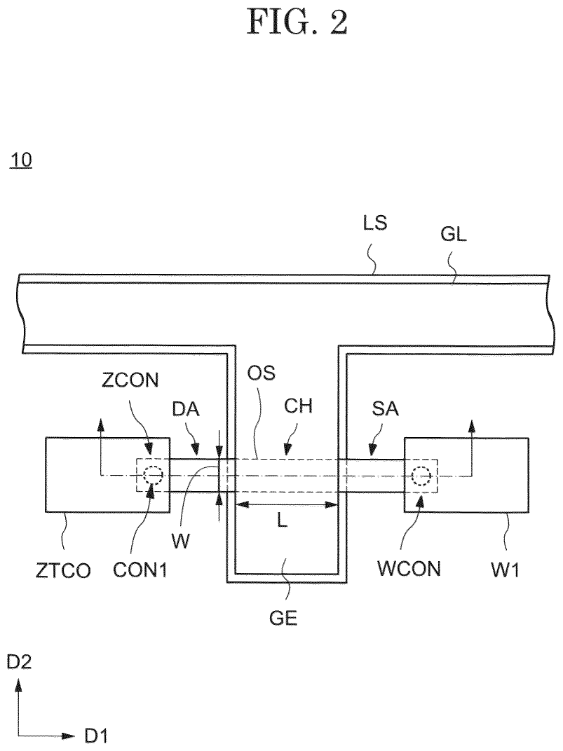

An outline of the semiconductor device 10 according to an embodiment of the present invention will be described with reference to FIG. 1 and FIG. 2. FIG. 1 is a cross-sectional view showing a configuration of the semiconductor device 10 according to an embodiment of the present invention. FIG. 2 is a plan view showing a configuration of the semiconductor device 10 according to an embodiment of the present invention. In addition, a cross-section taken along a dashed line in FIG. 2 corresponds to a cross-sectional view shown in FIG. 1.

As shown in FIG. 1, the semiconductor device 10 is arranged above a substrate SUB. The semiconductor device 10 includes at least an oxide semiconductor layer OS, a second insulating layer IL2, a gate electrode GE, a third insulating layer IL3, a wiring W1, a fourth insulating layer IL4, a transparent conductive layer ZTCO (also referred to as a connecting electrode), and a fifth insulating layer IL5. The semiconductor device 10 may further include a first insulating layer IL1 and a light-blocking layer LS. The oxide semiconductor layer OS, the second insulating layer IL2, and the gate electrode GE may be referred to as a transistor Tr. The transistor Tr may further include an aluminum-based metal oxide layer MO1 arranged in contact with the oxide semiconductor layer OS between the oxide semiconductor layer OS and the first insulating layer IL1. The gate electrode GE faces the oxide semiconductor layer OS. The second insulating layer IL2 is arranged between the oxide semiconductor layer OS and the gate electrode GE. In the present embodiment, although a top-gate transistor in which the oxide semiconductor layer OS is arranged closer to the substrate SUB than the gate electrode GE is exemplified, a bottom gate transistor in which the positional relationship between the gate electrode GE and the oxide semiconductor layer OS is reversed may be used.

The oxide semiconductor layer OS includes a channel region CA, a source region SA, and a drain region DA. The channel region CA is an oxide semiconductor layer in a region overlapping the gate electrode GE in a plan view. The channel region CA is switched between a conductive state and a non-conductive state in accordance with a voltage supplied to the gate electrode GE. The source region SA and the drain region DA are regions having lower resistance than the channel region. For example, the source region SA and the drain region DA are regions that have reduced resistance by ion-implanting impurities into the oxide semiconductor layer OS.

As shown in FIG. 2, a gate wiring GL is arranged along a first direction D1, and the gate electrode GE is arranged along a second direction D2. The gate electrode GE is a part of the gate wiring GL. The oxide semiconductor layers OS are arranged so as to cross the gate electrode GE.

The third insulating layer IL3 is arranged on the gate electrode GE. A wiring W1 is arranged on the third insulating layer IL3. The wiring W1 is arranged along the second direction D2. The wiring W1 is connected to the source region SA via contact holes WCON arranged in the second insulating layer IL2 and the third insulating layer IL3. The fourth insulating layer IL4 is arranged on the third insulating layer IL3 and the wiring W1. The transparent conductive layer ZTCO is arranged on the fourth insulating layer IL4. The transparent conductive layer ZTCO is connected to the drain regions DA via contact holes ZCON arranged in the second insulating layer IL2 to the fourth insulating layer IL4. The transparent conductive layers ZTCO are in contact with the drain regions DA at the bottom portions of the contact holes ZCON. A region where the transparent conductive layers ZTCO and the drain regions DA are in contact with each other is referred to as a contact region CON1. Here, TCO is an abbreviation for Transparent Conductive Oxide (transparent conductive oxide).

The light-blocking layer LS is arranged between the transistor Tr and the substrate SUB. In the present embodiment, the light-blocking layers LS1 and LS2 are provided as the light-blocking layer LS. However, the light-blocking layer LS may be formed only of the light-blocking layer LS1 or only of the light-blocking layer LS2. In a plan view, the light-blocking layer LS is arranged along the first direction D1 and the second direction D2, and is arranged in regions overlapping the gate lines GL and the gate electrodes GE. Further, the light-blocking layer LS is arranged so as to intersect with the oxide semiconductor layer OS. That is, in a plan view, the light-blocking layer LS is arranged in a region overlapping the channel region. The light-blocking layer LS inhibits light incident from the substrate SUB from reaching the channel region. In the case where a conductive layer is used as the light-blocking layer LS, the channel region may be controlled by applying a voltage to the light-blocking layer LS. In the case where a voltage is applied to the light-blocking layer LS, the light-blocking layer LS and the gate electrode GE may be electrically connected to each other. In a plan view, the contact region CON1 is arranged in a region that does not overlap the light-blocking layer LS.

In the case where the semiconductor device 10 is required to have high light transmittance, at least one of the source electrode and the drain electrode may be formed of a transparent conductive layer. For example, if a transparent conductive layer such as ITO is formed so as to be in contact with the silicon layer, the silicon layer is oxidized by a process gas and an oxygen ion at the time of the ITO film formation. Since the oxide layer formed on the surface of the silicon layer has high resistance, contact resistance between the silicon layer and the transparent conductive layer increases. As a result, electrical contact between the silicon layer and the transparent conductive layer is poor.

Similarly, in the case where the ITO film is formed so as to be in contact with the oxide semiconductor layer, immediately after the formation of the ITO film, a surface of the oxide semiconductor layer in the source region or the drain region, which has been made to have a low resistance, is oxidized by the process gas and the oxygen ion used during the ITO film formation. Even so, compared to forming the ITO film in contact with a silicon layer, although forming the ITO film in contact with an oxide semiconductor layer can reduce the contact resistance, there is room for improvement in the magnitude of the contact resistance between the ITO film and the oxide semiconductor layer. In addition, there arises a problem that the electrical characteristics of the transistor deteriorate due to the contact resistance.

In order to reduce the contact resistance, for example, it is desirable to reduce the oxide semiconductor layer oxidized in a subsequent step. For example, by forming the organic resin layer in contact with the ITO film after the ITO film is formed, water contained in the organic resin layer is supplied to the oxide semiconductor layer via the ITO film, whereby the oxide semiconductor layer can be reduced. However, a film thickness of the organic resin layer is several μm, and is sufficiently larger than a film thickness of the oxide semiconductor layer by several tens of nm. Therefore, a large amount of water contained in the organic resin layer is supplied to the oxide semiconductor layer more than necessary. As a result, reduction of the oxide semiconductor layer also occurs in the channel region, making it difficult to control the electrical characteristics of the transistor. In addition, it is difficult to control the amount of water supplied to a plurality of oxide semiconductor layers in the substrate surface. Therefore, the amount of water supplied to the plurality of oxide semiconductor layers varies, and the electrical characteristics of the transistor vary.

Therefore, in the semiconductor device 10 according to the embodiment of the present invention, in the case where the transparent conductive layer is connected to the oxide semiconductor layer, the contact resistance between the oxide semiconductor layer and the transparent conductive layer is reduced to improve the electrical characteristics. Alternatively, in the semiconductor device 10 according to the embodiment of the present invention, variations in the electrical characteristics of the transistor are reduced.

In the semiconductor device 10 shown in FIG. 1, the fifth insulating layer IL5 containing silicon nitride is arranged on the transparent conductive layer ZTCO. When forming a silicon nitride film, hydrogen can be included in the film by using a hydride as a film forming gas. By arranging the transparent conductive layer ZTCO in contact with the fifth insulating layer IL5 containing hydrogen, hydrogen contained in the fifth insulating layer IL5 can be supplied to the oxide semiconductor layer OS via the transparent conductive layer ZTCO.

The fifth insulating layer IL5 may include silicon nitride, may have a single-layer structure of a silicon nitride layer, or may have a stacked structure of a silicon nitride layer and a silicon oxide layer. A thickness of the fifth insulating layer IL5 is preferably 30 nm or more and 700 nm or less.

In the present embodiment, the fifth insulating layer IL5 is described using a silicon nitride layer in a single-layer configuration. In the case where the silicon nitride layer is used in a single-layer configuration, the thickness of the silicon nitride layer included in the fifth insulating layer IL5 is preferably 30 nm or more and 500 nm or more. In the case where the thickness of the silicon nitride layer is less than 30 nm, the quantity of hydrogen supplied to the oxide semiconductor layer in the contact portion is small, and the oxidized oxide semiconductor layer cannot be sufficiently reduced. Further, when the thickness of the silicon nitride layer exceeds 500 nm, hydrogen is excessively supplied to the oxide semiconductor layer, and hydrogen is diffused into the channel region, which makes it difficult to control the electric properties of the transistor.

By providing the fifth insulating layer IL5 including silicon nitride in contact with the transparent conductive layer ZTCO, contact resistance can be lowered by supplying hydrogen to the oxide semiconductor layer in the contact region CON1. In addition, the diffusion of hydrogen into the channel region can be suppressed, and the reduction of the oxide semiconductor layer in the channel region can be suppressed. Thus, the electrical characteristics of the transistor can be improved. According to the thickness of the fifth insulating layer IL5, the quantity of hydrogen supplied to the plurality of oxide semiconductor layers in the substrate surface can be controlled. Therefore, variations in the amount of hydrogen supplied to the plurality of oxide semiconductor layers can be suppressed, and variations in the electrical characteristics of the transistor can be suppressed.

### [1.2. Method for Manufacturing Semiconductor Device 10]

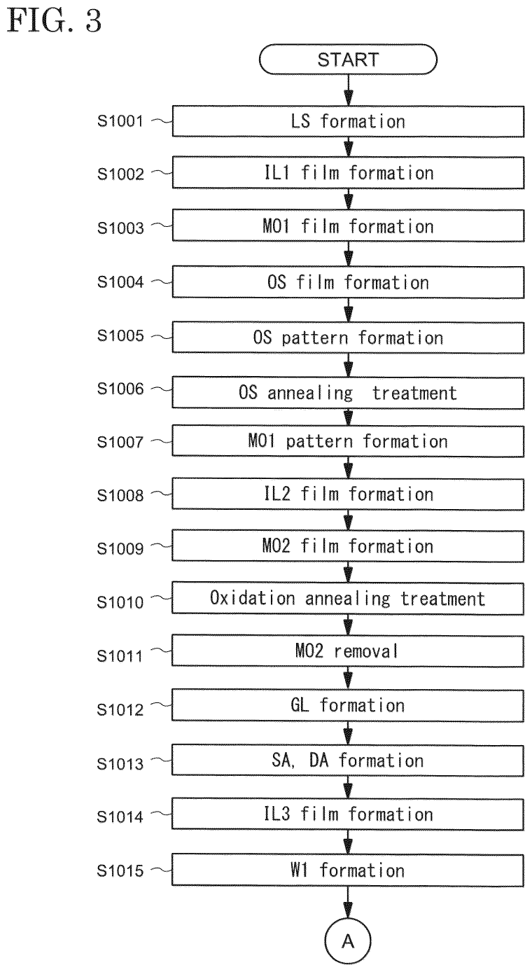

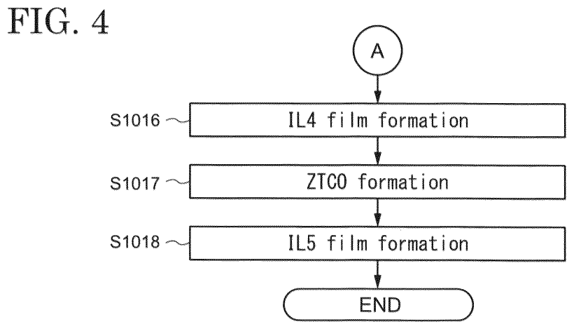

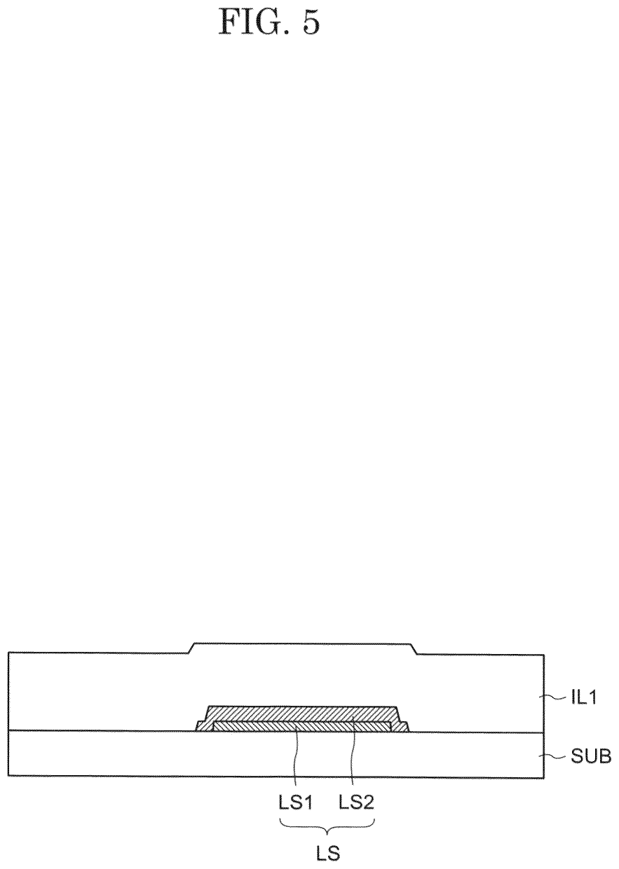

A method for manufacturing the semiconductor device 10 according to an embodiment of the present invention will be described. FIG. 3 and FIG. 4 are sequence diagrams showing a method for manufacturing the semiconductor device 10 according to an embodiment of the present invention. FIG. 5 to FIG. 12 are cross-sectional views showing a method for manufacturing the semiconductor device 10 according to an embodiment of the present invention.

First, the light-blocking layers LS1 and LS2 are formed as the light-blocking layer LS on the substrate SUB (see step S1001 shown in FIG. 3 and FIG. 5).

As the substrate SUB, a rigid substrate having translucency, such as a glass substrate, a quartz substrate, a sapphire substrate, or the like is used. In the case where the substrate SUB needs to have flexibility, a substrate containing an organic resin such as a polyimide substrate, an acryl substrate, a siloxane substrate, a fluorine resin substrate, or the like is used as the substrate SUB. In the case where a substrate containing an organic resin is used as the substrate SUB, an impurity element may be introduced into the organic resin in order to improve the heat resistance of the substrate SUB.

For example, the light-blocking layer LS is formed by processing a conductive layer formed by a sputtering method. A typical metallic material is used as the light-blocking layer LS. Examples of the light blocking-layer LS include aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof. As shown in FIG. 5, as the light-blocking layer LS, after the light-blocking layer LS1 is formed, the light-blocking layer LS2 is formed so as to cover the light-blocking layer LS1. In the present embodiment, although the light-blocking layer LS1 and the light-blocking layer LS2 are laminated, they may be formed as a single layer.

Next, the first insulating layer IL1 is formed as an underlayer on the light-blocking layer LS (see step S1002 shown in FIG. 3 and FIG. 5).

The first insulating layer IL1 is formed by a CVD (Chemical Vapor Deposition) method or the sputtering method. A typical insulating material is used as the first insulating layer IL1. As the first insulating layer IL1, for example, an inorganic insulating material such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), or the like is used.

SiOₓN_{y} and AlOₓN_{y} described above are silicon-containing and aluminum-containing compounds that contain a smaller proportion (x>y) of nitrogen (N) than oxygen (O). SiNₓO_{y} and AlNₓO_{y} are silicon-containing and aluminum-containing compounds that contain a lower proportion of oxygen than nitrogen (x>y).

The first insulating layer IL1 may have a single-layer structure or a laminated structure. In the case where the first insulating layer IL1 has the laminated structure, it is preferable that the insulating material containing nitrogen and the insulating material containing oxygen are formed in this order from the substrate SUB. By using an insulating material containing nitrogen, for example, it is possible to block impurities that diffuse from the substrate SUB to the oxide semiconductor layer OS. Further, by using an insulating material containing oxygen, oxygen can be released by a heat treatment. A temperature of the heat treatment in which the insulating material containing oxygen releases oxygen is, for example, 600° C. or less, 500° C. or less, 450° C. or less, or 400° C. or less. That is, the insulating material containing oxygen releases oxygen at a heat treatment temperature performed in a manufacturing process of a semiconductor device in the case where a glass substrate is used as the substrate SUB. In the present embodiment, for example, silicon nitride is formed as an insulating material containing nitrogen. Further, for example, silicon oxide is formed as an insulating material containing oxygen.

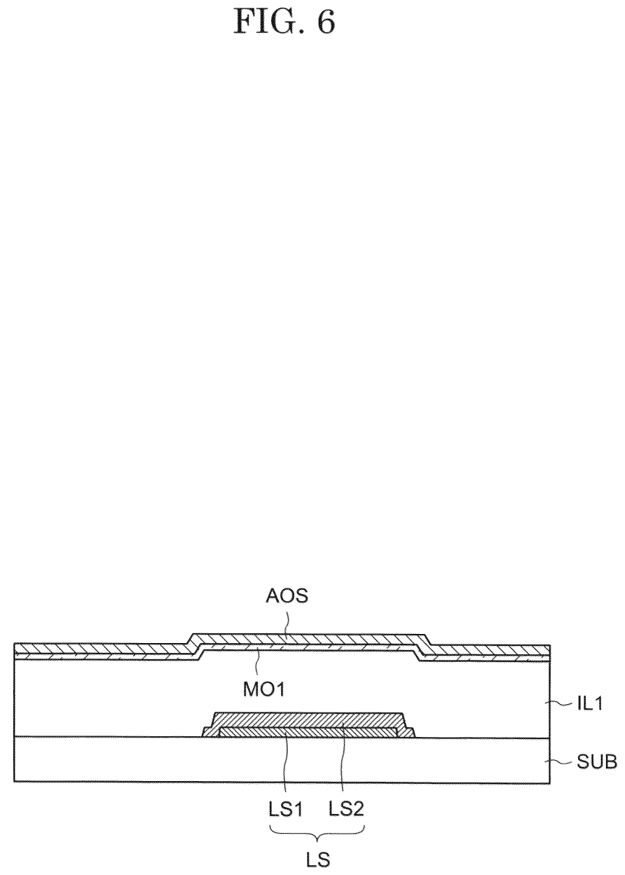

Next, the metal oxide layer MO1 containing aluminum as a main component is formed on the first insulating layer IL1 (see step S1003 shown in FIG. 3 and FIG. 6).

The metal oxide layer MO1 is formed by the sputtering method. As the metal oxide layer containing aluminum as a main component, for example, an inorganic insulating layer such as aluminum oxide (AlOₓ), aluminum oxynitride (AlOₓN_{y}), aluminum nitride oxide (AlNₓO_{y}), aluminum nitride (AlNₓ), or the like is used. The “metal oxide layer containing aluminum as a main component” means that the proportion of aluminum contained in the metal oxide layer MO1 is 1% or more of the total amount of the metal oxide layer MO1. The ratio of the aluminum contained in the metal oxide layer MO1 may be 5% or more and 70% or less, 10% or more and 60% or less, or 30% or more and 50% or less of the entire metal oxide layer MO1. The ratio described above may be a mass ratio or a weight ratio.

A film thickness of the metal oxide layer MO1 is, for example, 1 nm or more and 10 nm or less, 1 nm or more and 4 nm or less, or 1 nm or more and 3 nm or less. In the present embodiment, aluminum oxide is used as the metal oxide layer MO1. Aluminum oxide has a high barrier property against gas.

Next, an amorphous oxide semiconductor layer AOS is formed on the metal oxide layer MO1 (see step S1004 shown in FIG. 3 and FIG. 6).

The oxide semiconductor layer AOS is deposited by the sputtering method or atomic layer deposition method (ALD: Atomic Layer Deposition). A thickness of the oxide semiconductor layer AOS is, for example, 5 nm or more and 50 nm or less, preferably 10 nm or more and 40 nm or less, and more preferably 10 nm or more and 30 nm or less.

As the oxide semiconductor layer AOS, a metal oxide having semiconductor properties can be used.

In the case where the oxide semiconductor layer AOS is formed by the sputtering method, the oxide semiconductor layer AOS is formed while controlling the temperature of the object to be film-formed (the substrate SUB and the structure formed thereon).

If film formation is performed on the object to be film-formed by the sputtering method, ions generated in the plasma and the atoms recoiled from a sputtering target collide with the object to be film-formed, so that the temperature of the object to be film-formed increases with the film forming process. In order to control the temperature of the object to be film-formed as described above, for example, film formation may be performed while cooling the object to be film-formed. For example, the object to be film-formed may be cooled from a surface opposite to a film-forming surface so that a temperature of the film-forming surface of the object to be film-formed (hereinafter, referred to as “film-forming temperature”) is 100° C. or less, 70° C. or less, 50° C. or less, or 30° C. or less.

Next, the oxide semiconductor layer AOS is patterned (step S1005 shown in FIG. 3). Although not shown, a resist mask is formed on the oxide semiconductor layer AOS, and the oxide semiconductor layer AOS is etched using the resist mask. Wet etching may be used, or dry etching may be used for etching the oxide semiconductor layer AOS. Wet etching may be performed using an acidic etchant. For example, oxalic acid or hydrofluoric acid may be used as the etchant.

The oxide semiconductor layer AOS is preferably patterned prior to an OS annealing process. Further, even if the oxide semiconductor layer AOS is damaged by the etching, the damage can be repaired by an OS annealing treatment.

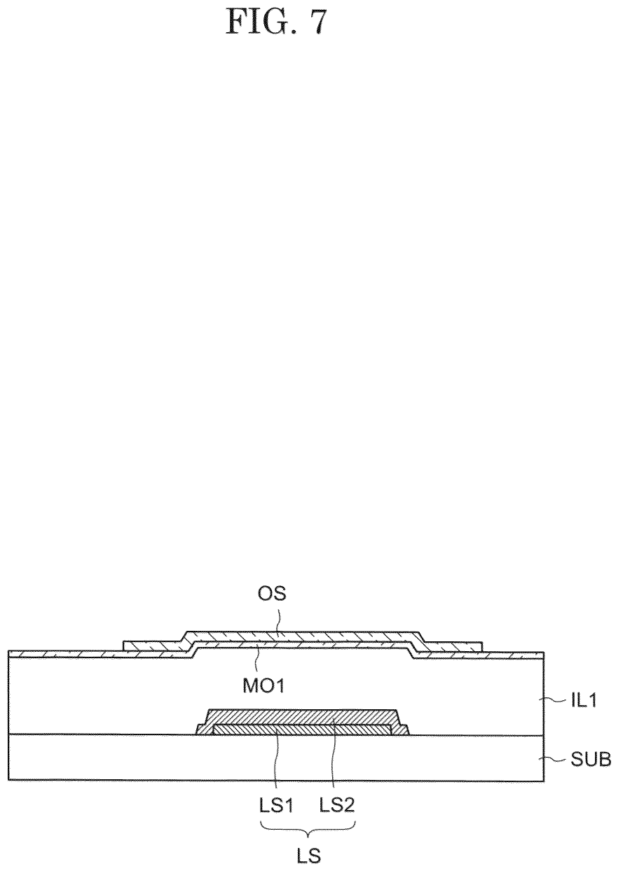

After the oxide semiconductor layer AOS is patterned, the oxide semiconductor layer AOS is subjected to a heat treatment (OS annealing treatment) (step S1006 shown in FIG. 3 and FIG. 7). In the OS annealing treatment, the oxide semiconductor layer AOS is held at a predetermined reaching temperature for a predetermined period of time. The predetermined reaching temperature is 300° C. or more and 500° C. or less, preferably 350° C. or more and 450° C. or less. The holding time at the reaching temperature is 15 minutes or more and 120 minutes or less, preferably 30 minutes or more and 60 minutes or less. The oxide semiconductor layer OS is formed by performing the OS annealing treatment.

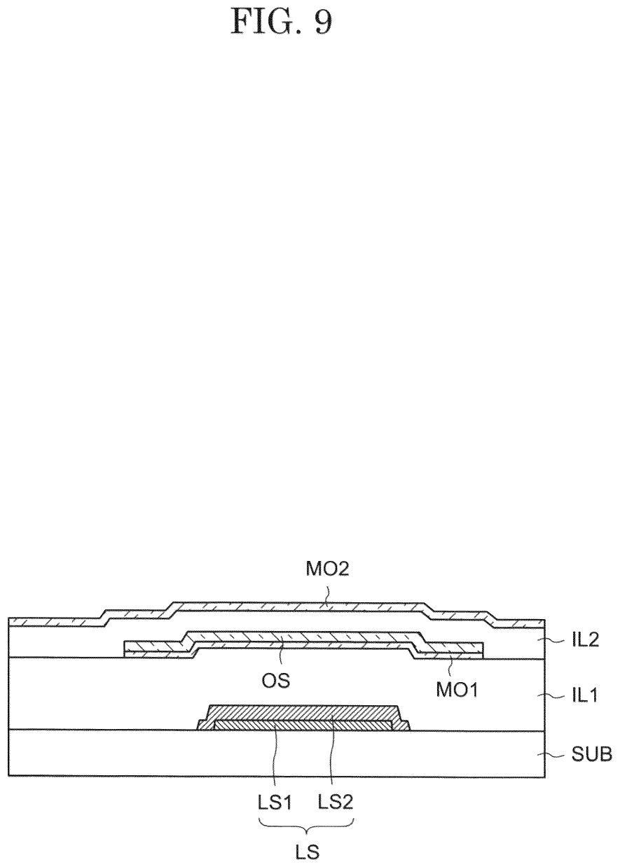

Next, the second insulating layer IL2 is formed on the oxide semiconductor layer OS (step S1008 shown in FIG. 3 and FIG. 9).

For the film formation method and insulating material of the second insulating layer IL2, refer to the description of the first insulating layer IL1. Further, a thickness of the second insulating layers IL2 is, for example, 50 nm or more and 300 nm or less, preferably 60 nm or more and 200 nm or less, and more preferably 70 nm or more and 150 nm or less.

It is preferable to use an oxygen-containing insulating material as the second insulating layer IL2. It is preferable to use an insulating layer having less imperfections as the second insulating layer IL2. For example, in the case where a composition ratio of oxygen in the second insulating layer IL2 and a composition ratio of oxygen in an insulating layer having the same composition as that of the second insulating layer IL2 (hereinafter referred to as “other insulating layer”) are compared, the composition ratio of oxygen in the second insulating layer IL2 is closer to a stoichiometric ratio with respect to the insulating layer than the composition ratio of oxygen in the other insulating layer. For example, in the case where silicon oxide (SiOₓ) is used for each of the second insulating layer IL2 and the third insulating layer IL3, the composition ratio of oxygen in the silicon oxide used as the second insulating layer IL2 is closer to the stoichiometric ratio of silicon oxide than the composition ratio of oxygen in the silicon oxide used as the third insulating layer IL3. For example, as the second insulating layer IL2, a layer in which no defects are observed when evaluated by electron-spin resonance (ESR) may be used.

The second insulating layer IL2 may be formed at a film-forming temperature of 350° C. or higher in order to form an insulating layer having less defects as the second insulating layer IL2. In addition, after the second insulating layer IL2 is formed, the second insulating layer IL2 may be partially implanted with oxygen. In the present embodiment, as the second insulating layer IL2, silicon oxide is formed at a film-forming temperature of 350° C. or higher in order to form an insulating layer having less defects.

Next, a metal oxide layer MO2 containing aluminum as a main component is formed on the second insulating layer IL2 (step S1009 shown in FIG. 3 and FIG. 9).

For the film formation method and insulating material of the metal oxide layer MO2, refer to the description of the metal oxide layer MO1 described above. Oxygen is implanted into the second insulating layer IL2 by forming the metal oxide layer MO2. A thickness of the metal oxide layer MO2 is, for example, 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer MO2. Aluminum oxide has a high barrier property against gas. In the present embodiment, the aluminum oxide used as the metal oxide layer MO2 suppresses the oxygen implanted into the second insulating layer IL2 from diffusing outward when the metal oxide layer MO2 is formed.

For example, in the case where the metal oxide layer MO2 is formed by the sputtering method, the process gas used in the sputtering remains in the film of the second insulating layer IL2. For example, in the case where Ar is used as the process gas for sputtering, Ar may remain in the film of the second insulating layer IL2. The remaining Ar can be detected by a SIMS (Secondary Ion Mass Spectrometry) spectrometry with respect to the second insulating layer IL2.

A heat treatment (oxidation annealing treatment) for supplying oxygen to the oxide semiconductor layer OS is performed while the second insulating layer IL2 is formed on the oxide semiconductor layer OS and the metal oxide layer MO2 is formed on the second insulating layer IL2 (step S1010 shown in FIG. 3 and FIG. 9).

Many oxygen defects are generated on an upper surface and a side surface of the oxide semiconductor layer OS in a process from when the oxide semiconductor layer OS is formed until when the second insulating layer IL2 is formed on the oxide semiconductor layer OS. Oxygen emitted from the first insulating layer IL1 is supplied to the upper surface and the side surface of the oxide semiconductor layer OS by the oxidation annealing treatment, and the oxygen deficiency is repaired.

In the oxidation annealing treatment described above, the oxygen implanted in the second insulating layer IL2 is blocked by the metal oxide layer MO2, so that the oxygen is suppressed from being released into the atmosphere. Therefore, the oxygen is efficiently supplied to the oxide semiconductor layer OS by the oxidation annealing treatment, and the oxygen deficiency is repaired.

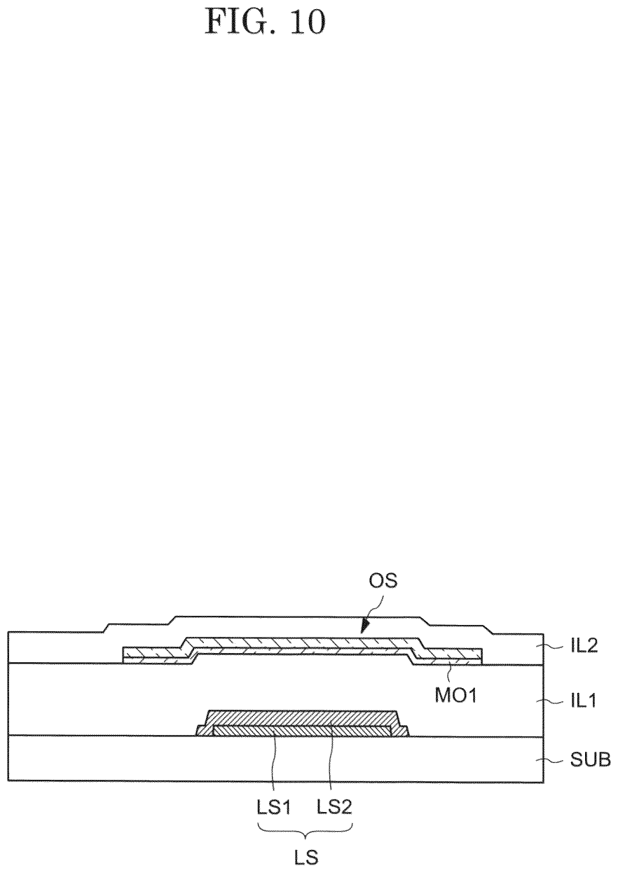

Next, after the oxidation annealing treatment, the metal oxide layer MO2 is etched (removed) (step S1011 shown in FIG. 3 and FIG. 10). Wet etching may be used, or dry etching may be used for etching the metal oxide layer MO2. For example, dilute hydrofluoric acid (DHF) is used as the wet etching. By performing the etching process, the metal oxide layer MO2 formed on the entire surface is removed. In other words, the metal oxide layer MO2 is removed without using a mask. In other words, all the metal oxide layer MO2 in the regions overlapping the oxide semiconductor layer OS formed in one pattern is removed by etching at least in a plan view.

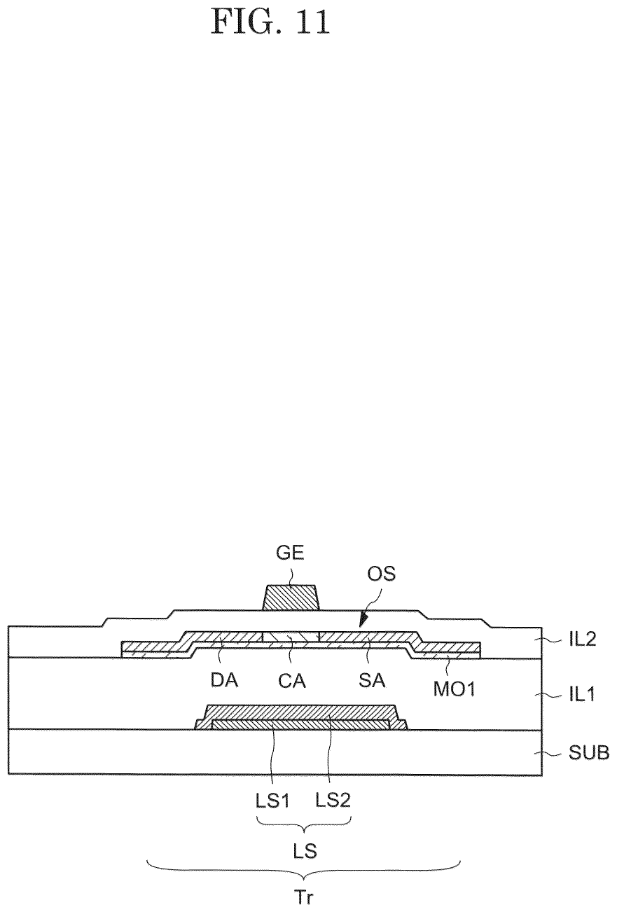

Next, the gate electrode GE is formed on the second insulating layer IL2 (step S1012 shown in FIG. 3 and FIG. 11). For the film formation method and insulating material of the gate electrode GE, refer to the explanation of the light-blocking layer LS.

Next, using the gate electrode GE as a mask, an impurity is added to the oxide semiconductor layer OS (step S1013 shown in FIG. 3 and FIG. 11). In the present embodiment, the case where the impurity is added by ion implantation is described, but it may be performed by an ion doping method.

Specifically, by ion-implantation, an impurity element is added to the oxide semiconductor layer OS through the second insulating layer IL2, thereby forming the source region SA and the drain region DA. For example, argon (Ar), phosphorus (P), or boron (B) may be used as the impurity element. For example, in the case where boron (B) is added by the ion-implantation method, an acceleration energy may be set to be 20 keV or more and 40 keV or less, and an implantation amount of boron (B) may be set to be 1×10¹⁴ cm⁻² or more and 1×10¹⁶ cm⁻² or less.

Concentrations of the impurity elements contained in the source region SA and the drain region DA are preferably 1×10¹⁸ cm⁻³ or more and 1×10²¹ cm⁻³ or less as measured by the SIMS (secondary ion-mass spectrometry). Further, in the case where the source region SA and the drain region DA contain 1×10¹⁸ cm⁻³ or more and 1×10²¹ cm⁻³ or less, it is presumed that an impurity element is intentionally added by an ion-implantation method or the doping method.

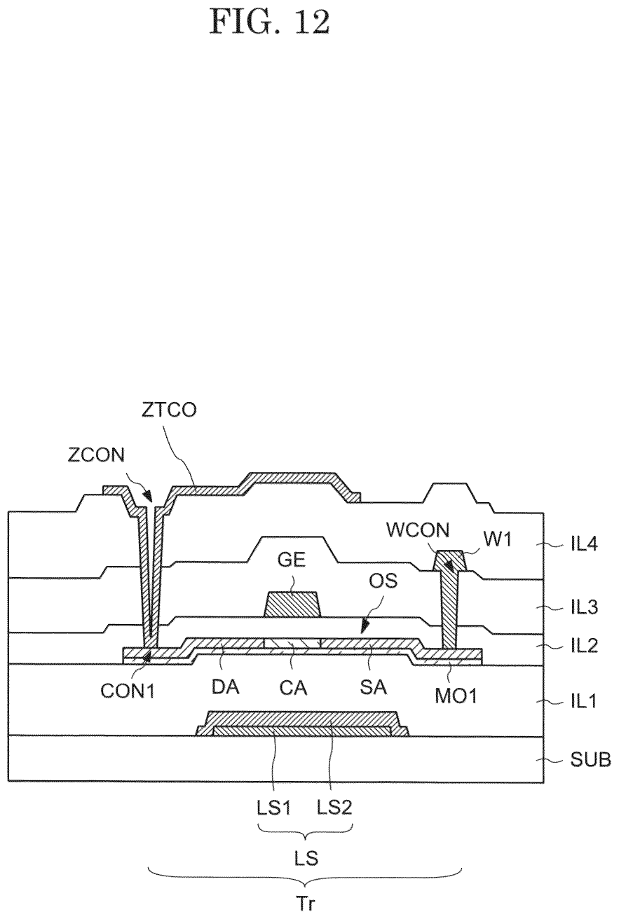

Next, the third insulating layer IL3 is formed on the second insulating layer IL2 and the gate electrode GE (step S1014 shown in FIG. 3 and FIG. 12). The third insulating layer IL3 may be formed using the first insulating layer IL1 described above.

Next, a contact hole WCON reaching the source region SA is formed in the third insulating layers IL3. Thereafter, the wiring W1 is formed on the third insulating layers IL3, and the wiring W1 is connected to the source region SA via the contact hole ZCON (step S1015 shown in FIG. 3). For the film formation method and insulating material of the wiring W1, refer to the description of the light-blocking layer LS.

Next, the fourth insulating layer IL4 is formed on the third insulating layer IL3 and the wiring W1 (step S1016 shown in FIG. 4 and FIG. 12). For the film formation method and insulating material of the fourth insulating layer IL4, refer to the description of the first insulating layer IL1 described above.

Next, the contact hole ZCON reaching the drain regions DA is formed in the fourth insulating layers IL4. Thereafter, the transparent conductive layer ZTCO is formed on the fourth insulating layer IL4, and the transparent conductive layer ZTCO is connected to the drain regions DA via the contact holes ZCON (step S1017 shown in FIG. 4 and FIG. 12).

The transparent conductive layer ZTCO is formed by processing a transparent oxide conductive layer formed by the sputtering method. A transparent conductive material such as a mixture of indium oxide and tin oxide (ITO), a mixture of indium oxide and zinc oxide (IZO), or the like can be used as the transparent conductive layer ZTCO. A transparent conductive material other than the above may be used as the transparent conductive layer ZTCO.

As described above, when the transparent conductive layer ZTCO is formed, the oxide semiconductor layer OS is oxidized by the process gas or the oxygen ion. Therefore, the oxidized oxide semiconductor layer OS needs to be reduced.

In the present embodiment, the fifth insulating layer IL5 containing silicon nitride is formed in contact with the transparent conductive layer ZTCO (step S1018 shown in FIG. 4 and FIG. 1).

The fifth insulating layers IL5 are formed by the sputtering method or the CVD method. The fifth insulating layer IL5 is formed in a single-layer structure of a silicon nitride layer or a stacked structure of a silicon oxide layer and a silicon nitride layer. Silicon nitride oxide (SiNₓO_{y}) may be used as the silicon nitride included in the fifth insulating layer IL5. A thickness of the fifth insulating layers IL5 is preferably 30 nm or more and 700 nm or less.

In the case where the ITO is used as the transparent conductive layer ZTCO, a silicon nitride layer is deposited on the ITO film at a film-forming temperature of 350° C. or higher. However, since the ITO film is reduced during the formation of the silicon nitride layer, irregularities are formed on the ITO film. As a result, the ITO film may be short-circuited or transmittance of the ITO film may be reduced.

Therefore, in the case where a single layer of a silicon nitride layer is formed in contact with the transparent conductive layer ZTCO, the film is preferably formed at a temperature of 150° C. or higher and 250° C. or lower. In this case, a thickness of the silicon nitride layers is preferably 30 nm or more and 500 nm or less.

In this way, by forming the silicon nitride layer as the fifth insulating layer IL5 at 150° C. or higher and 250° C. or lower, reduction of the transparent conductive layer ZTCO during film formation can be suppressed. As a result, it is possible to suppress the occurrence of irregularities on a surface of the transparent conductive layer ZTCO. It is possible to suppress short-circuiting of the transparent conductive layer ZTCO caused by irregularities occurring on the surface of the transparent conductive layer ZTCO and a decrease in the transmittance of light.

Further, by setting a thickness of the silicon nitride layer to be 30 nm or more and 500 nm or less, it is possible to supply a quantity of hydrogen suitable for reducing the oxidized oxide semiconductor layer to the oxide semiconductor layer. Thus, contact resistance between the transparent conductive layer ZTCO and the oxide semiconductor layer OS can be reduced. In addition, it is possible to suppress a diffusion of hydrogen into the channel region CH, and thus it is easy to control the electrical properties of the transistor. Furthermore, variations in the amount of hydrogen supplied to the plurality of oxide semiconductor layers in the substrate surface can be suppressed. As a result, it is possible to prevent variations in the electrical characteristics of the transistor from occurring.

Through the above steps, the semiconductor device 10 can be manufactured.

Mobility in the present embodiment is a field-effect mobility in a saturated region of the transistor, and means a maximal value of the field-effect mobility in a region in which a potential difference (Vd) between the source electrode and the drain electrode is larger than a value (Vg−Vth) obtained by subtracting a threshold voltage (Vth) of the transistor from a voltage (Vg) supplied to the gate electrode.

### [1.3. Modification 1]

In the semiconductor device 10 according to the present embodiment, the metal oxide layer MO1 or the metal oxide layer MO2 may be omitted.

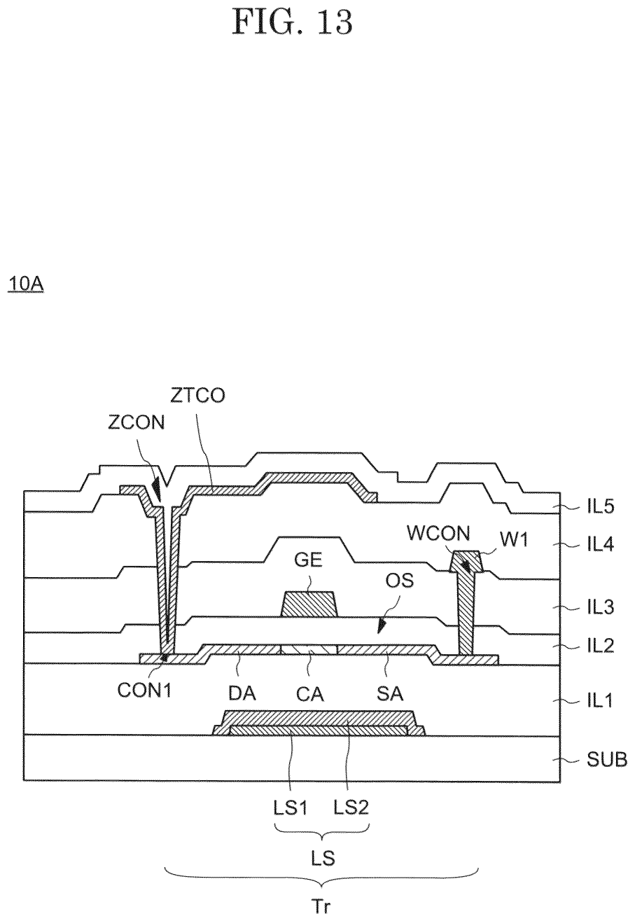

In the case where the metal oxide layer MO1 is omitted, the step of forming the metal oxide layer MO1 and the step of patterning the metal oxide layer MO1 arranged on the first insulating layer IL1 may be omitted in the manufacturing process of the semiconductor device 10. These steps correspond to step S1003 and step S1007 shown in FIG. 3. In the case where the metal oxide layer MO1 is omitted, the configuration of the semiconductor device is the configuration of the semiconductor device 10A shown in FIG. 13. As in the semiconductor device 10A shown in FIG. 13, the oxide semiconductor layer OS is arranged in contact with the first insulating layer IL1.

In the case where the metal oxide layer MO2 is omitted, the step of forming the metal oxide layer MO2 on the second insulating layer IL2 and then performing the annealing process may be omitted in the manufacturing process of the semiconductor device 10. Step S1009 and step S1011 shown in FIG. 3 may be omitted for these steps. In the case where the metal oxide layer MO2 is omitted, the configuration of the semiconductor device is the same as that of the semiconductor device 10 shown in FIG. 1.

### [1.4. Modification 2]

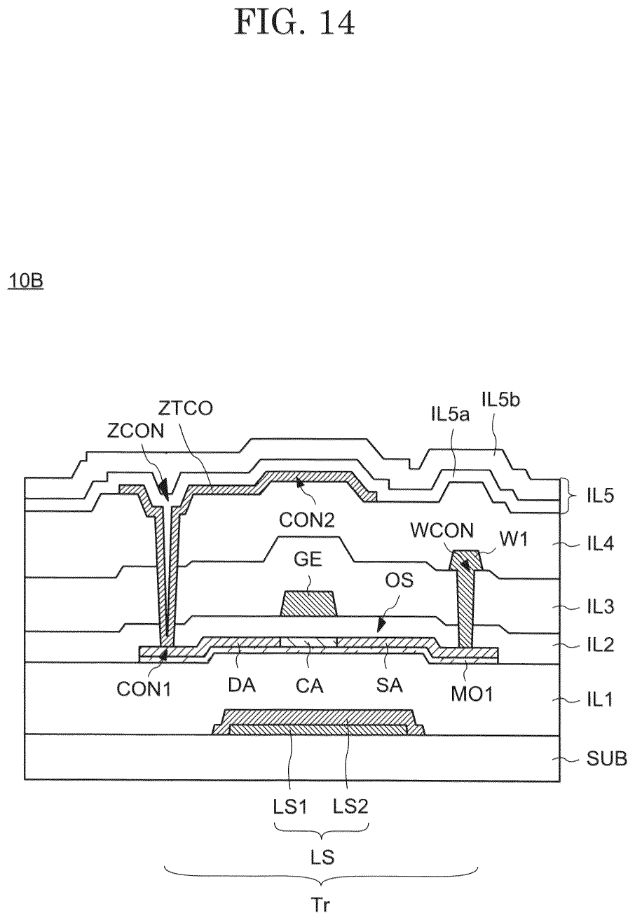

A case where the fifth insulating layer IL5 has a stacked structure in the semiconductor device 10 of this embodiment will be described with reference to FIG. 14. In the following description, the configuration of the fifth insulating layer IL5 will be described in detail, and detailed description of other configurations which are the same as the semiconductor device 10 will be omitted.

FIG. 14 is a cross-sectional view of the semiconductor device 10B according to an embodiment of the present disclosure. In the semiconductor device 10B shown in FIG. 14, a stacked structure including a silicon oxide layer IL5a and a silicon nitride layer IL5b formed on the silicon oxide layer IL5a is used as the fifth insulating layer IL5. The silicon oxide layer IL5a is arranged in contact with the transparent conductive layer ZTCO. In the present modification, a thickness of the fifth insulating layer IL5 is preferably 30 nm or more and 700 nm or less together with the silicon oxide layer IL5a and the silicon nitride layer IL5b. Further, the silicon oxide layer IL5a and the silicon nitride layer IL5b are formed at 150° C. or higher and 400° C. or lower.

A film thickness of the silicon oxide layer IL5a is preferably smaller than a film thickness of the silicon nitride layer IL5b. Specifically, the film thickness of the silicon oxide layer IL5a is preferably, for example, 30 nm or more and 70 nm or less, and the film thickness of the silicon nitride layer IL5b is preferably, for example, 30 nm or more and 500 nm or less.

As described above, in the case where the silicon nitride layer is formed in contact with the transparent conductive layer ZTCO in the semiconductor device 10, if the temperature is 350° C. or higher, the transparent conductive layer ZTCO is reduced during film formation. On the other hand, reduction of the transparent conductive layer ZTCO can be suppressed by forming the silicon oxide layer IL5a in contact with the transparent conductive layer ZTCO and forming the silicon nitride layer IL5b on the silicon oxide layer IL5a at a film-forming temperature of 350° C. or higher. Further, by setting the thickness of the silicon oxide layer IL5a to be 30 nm or more and 70 nm or less, hydrogen contained in the silicon nitride layer IL5b can be supplied to the oxide semiconductor layer OS via the silicon oxide layer IL5a and the transparent conductive layer ZTCO. Thus, the contact resistance between the oxide semiconductor layer OS and the transparent conductive layer ZTCO can be reduced. In addition, it is possible to suppress the diffusion of hydrogen into the channel region CH, and thus it is easy to control the electrical properties of the transistor. Furthermore, variations in the amount of hydrogen supplied to the plurality of oxide semiconductor layers in the substrate surface can be suppressed. As a result, it is possible to prevent variations in the electrical characteristics of the transistor from occurring.

### [1.5. Modification 3]

Even in the case where IGZO is used as the oxide semiconductor material, in the case where IGZO is connected to the transparent conductive layer ZTCO, the fifth insulating layer IL5 containing silicon nitride is preferably arranged in contact with the transparent conductive layer ZTCO. The fifth insulating layer IL5 may have a single-layer structure of a silicon nitride layer or a stacked structure of a silicon oxide layer and a silicon nitride layer. Further, in the case where the fifth insulating layer IL5 has a laminated structure, a film thickness is preferably 30 nm or more and 700 nm or less, and in the case where the fifth insulating layer IL5 is formed into a single-layer structure, it is preferably 30 nm or more and 500 nm or less. Accordingly, a suitable amount of hydrogen can be supplied to the oxide semiconductor layer to reduce the oxidized oxide semiconductor layer. The contact resistance between the transparent conductive layer ZTCO and the oxide semiconductor layer can be reduced. In addition, it is possible to suppress the diffusion of hydrogen into the channel region CH, and thus it is easy to control the electrical properties of the transistor. Furthermore, variations in the amount of hydrogen supplied to the plurality of oxide semiconductor layers in the substrate surface can be suppressed. As a result, it is possible to prevent variations in the electrical characteristics of the transistor from occurring.

### Second Embodiment

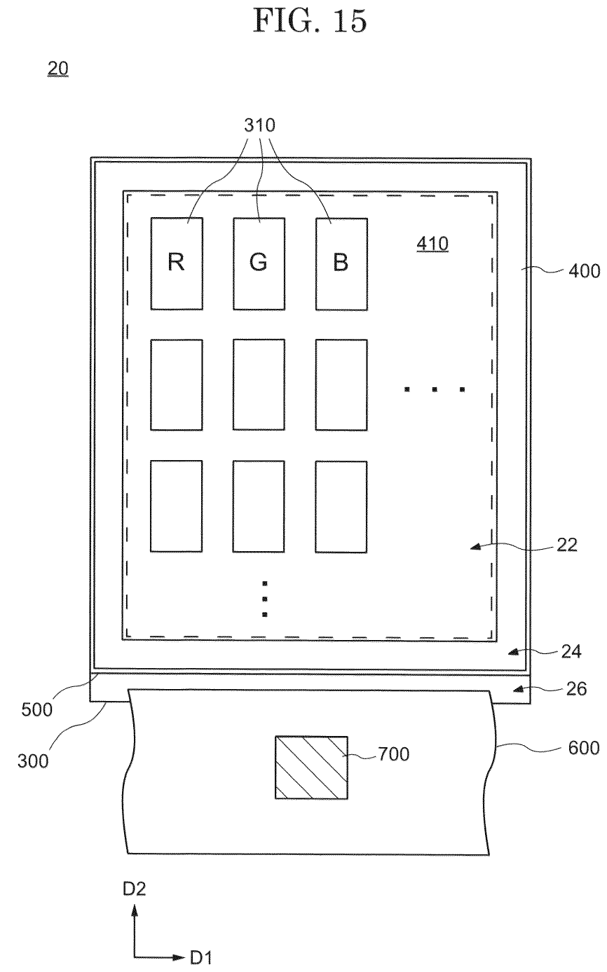

In the present embodiment, display devices 20 and 20A according to an embodiment of the present disclosure will be described referring to FIG. 15 to FIG. 21.

### [2.1. Overview of Display Device 20]

FIG. 15 is a plan view showing an outline of the display device 20 according to an embodiment of the present invention. In the present embodiment, a configuration of a liquid crystal display device as the display device 20 will be described.

As shown in FIG. 15, the display device 20 includes an array substrate 300, a sealing portion 400, a counter substrate 500, a flexible printed circuit board 600 (FPC), and an IC chip 700. The array substrate 300 and the counter substrate 500 are bonded to each other by the sealing portion 400. In a liquid crystal region 22 surrounded by the sealing portion 400, a plurality of pixels 310 is arranged in a matrix along the first direction D1 (row direction) and the second direction D2 (column direction) intersecting the first direction D1. The plurality of pixels 310 includes a red pixel R, a green pixel G, and a blue pixel B according to a color filter arranged on the counter substrate. Each of the red pixel R, the green pixel G, and the blue pixel B is also referred to as a sub-pixel. The first direction D1 and the second direction D2 may be perpendicular to each other. The liquid crystal region 22 is a region overlapping a liquid crystal element 410 described later in a plan view. In the following description, a region including a plurality of pixels in the liquid crystal region 22 may be referred to as an image display region or an active region.

In addition, the display device 20 includes a backlight unit on the back of the array substrate 300, and when the light emitted from the backlight unit passes through the image display region, the transmitted light is modulated in each pixel to display an image.

The sealing region 24 in which the sealing portion 400 is arranged is a region around the liquid crystal region 22. The FPC 600 is arranged in a terminal region 26. The terminal region 26 is a region where the array substrate 300 is exposed from the counter substrate 500, and is provided outside the sealing region 24. In addition, the outside of the sealing region 24 means the outside of the region where the seal portion 400 is arranged and the region surrounded by the sealing portion 400. The IC chip 700 is arranged on the FPC 600. The IC chip 700 supplies signals for driving the pixel circuits of the respective pixels 310. In addition, in the following description, the sealing region 24 other than the image display region, the outside of the sealing region 24, and the terminal region 26 may be collectively referred to as a peripheral region.

### [2.2. Circuit Configuration of Display Device 20]

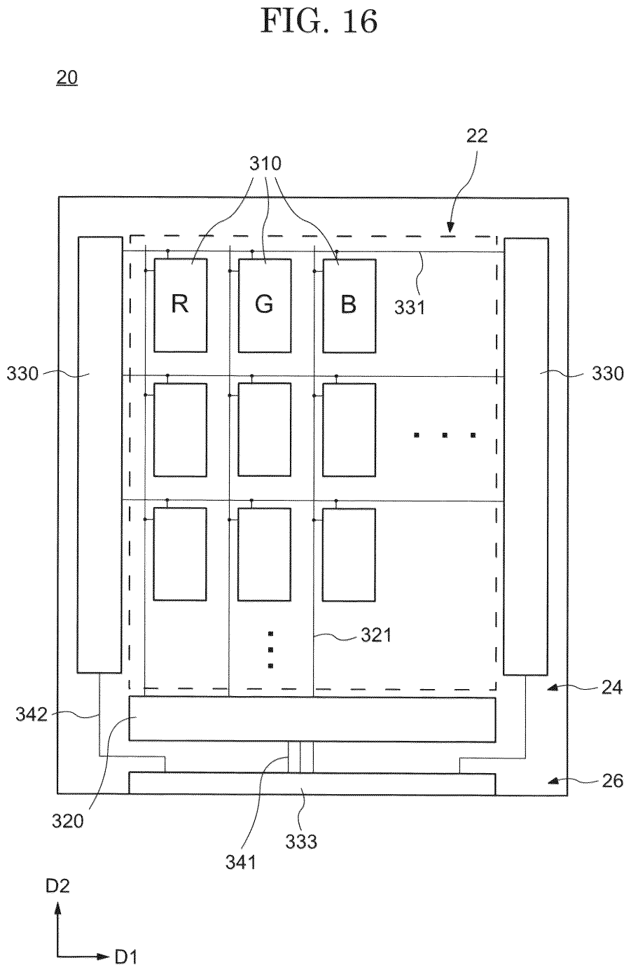

FIG. 16 is a block diagram showing a circuit configuration of the display device 20 according to an embodiment of the present invention. As shown in FIG. 16, a gate driver circuit 330 is arranged at a position adjacent to the liquid crystal region 22 in which the pixel 310 is arranged in the first direction D1, and a source driver circuit 320 is arranged at a position adjacent to the liquid crystal region 22 in the second direction D2. The source driver circuit 320 and the gate driver circuit 330 are arranged in the sealing region 24. However, the region in which the source driver circuit 320 and the gate driver circuit 330 are arranged is not limited to the sealing region 24, and may be any region as long as it is outside the region in which the pixel circuit of the pixel 310 is arranged.

A gate wiring 331 extends from the gate driver circuit 330 in the first direction D1 and is connected to the pixel circuits of the plurality of pixels 310 arranged in the first direction D1. A source wiring 321 extends from the source driver circuit 320 in the second direction D2 and is connected to the pixel circuits of the plurality of pixels 310 arranged in the second direction D2.

A terminal portion 333 is arranged in the terminal region 26. The terminal portion 333 and the source driver circuit 320 are connected by a connection wiring 341. Similarly, the terminal portion 333 and the gate driver circuit 330 are connected by a connection wiring 342. When the FPC 600 is connected to the terminal portion 333, an external device to which the FPC 600 is connected and the display device 20 are connected, and pixel circuits included in the respective pixels 310 arranged in the display device 20 are driven by signals from the external device.

### [2.3. Pixel Circuit of Pixel 310 of Display Device 20]

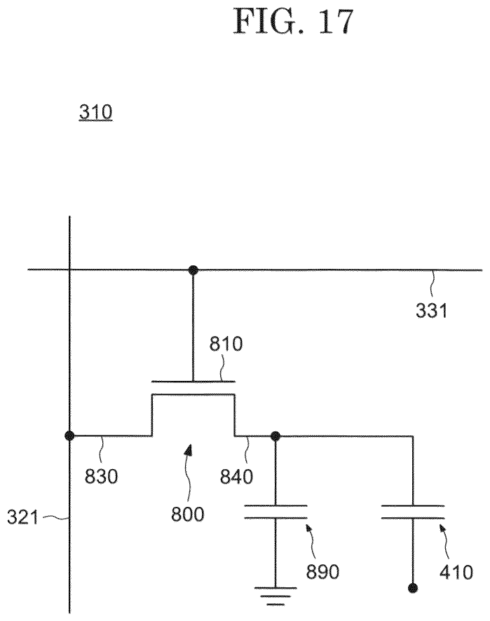

FIG. 17 is a circuit diagram showing a pixel circuit of the pixel 310 of the display device 20 according to an embodiment of the present invention. As shown in FIG. 17, the pixel circuit includes elements such as a transistor 800, a holding capacitance 890, and the liquid crystal element 410. One electrode of the holding capacitance 890 is a transparent conductive layer PTCO, and the other electrode is a transparent conductive layer CTCO, which will be described later. Similarly, one electrode of the liquid crystal device 410 is the transparent conductive layer PTCO, and the other electrode is the transparent conductive layer CTCO. The transistor 800 includes a gate electrode 810, a source electrode 830, and a drain electrode 840. The gate electrode 810 is connected to the gate wiring 331. The source electrode 830 is connected to the source wiring 321. The drain electrode 840 is connected to the holding capacitance 890 and the liquid crystal element 410. In addition, in the present embodiment, for convenience of explanation, although 830 is referred to as a source electrode, and 840 is referred to as a drain electrode, each of the electrodes may be replaced with a function as a source and a function as a drain.

### [2.4. Configuration of Display Device 20]

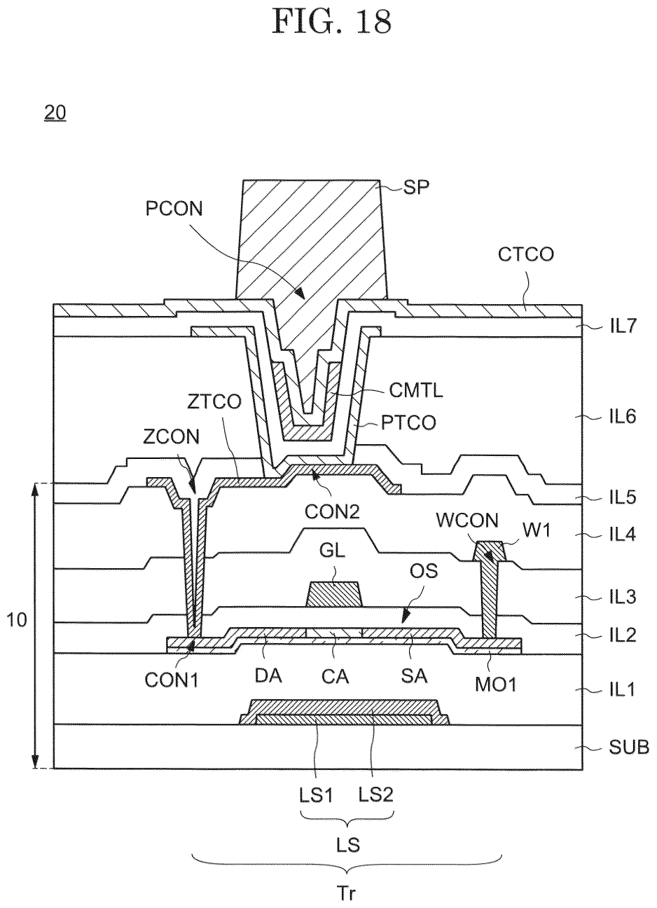

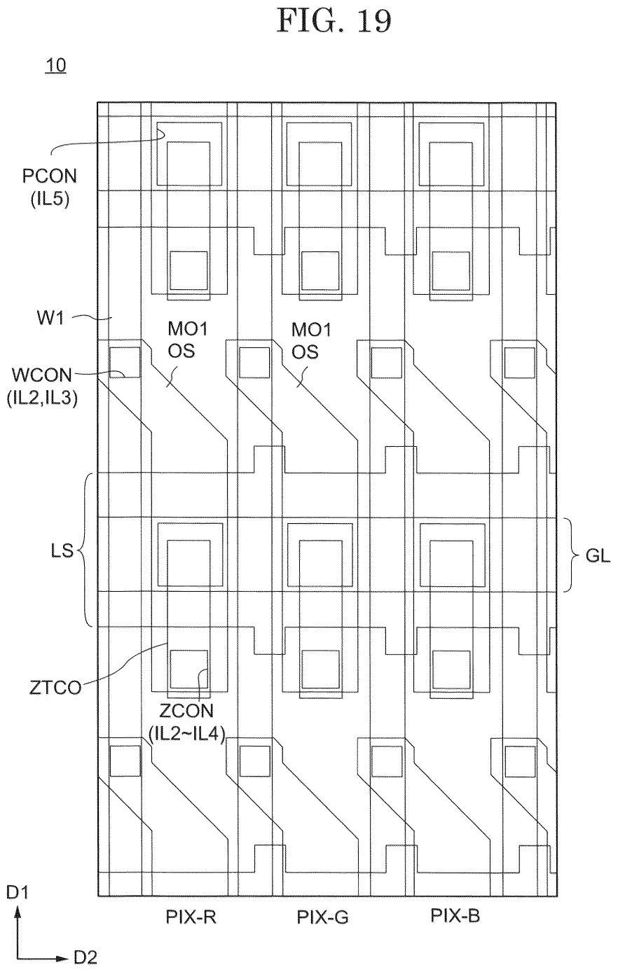

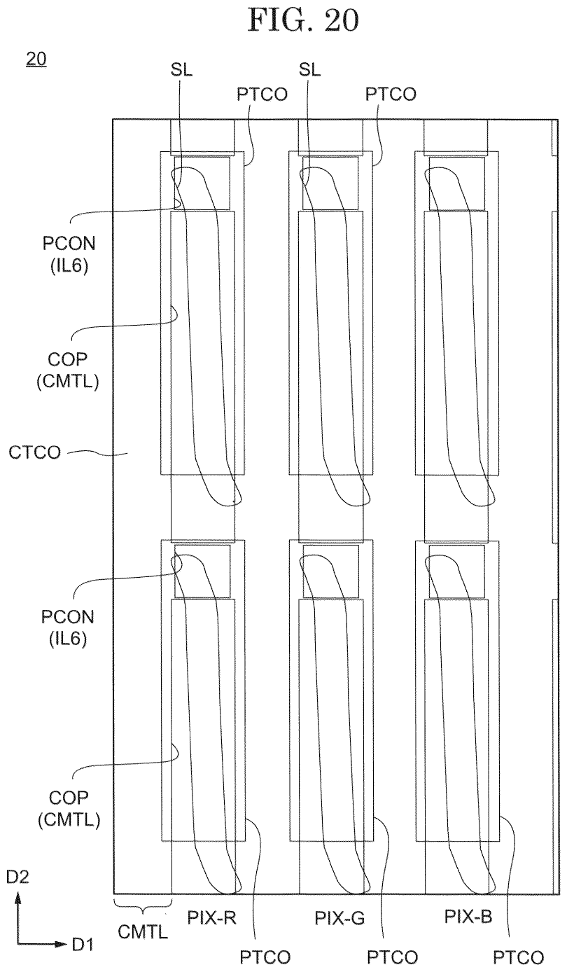

Referring to FIG. 18 to FIG. 20, a configuration of the display device 20 including the semiconductor device 10 according to an embodiment of the present invention will be described in detail. FIG. 18 is a cross-sectional view showing a configuration of the display device 20 including the semiconductor device 10 according to an embodiment of the present invention. FIG. 19 is a plan view showing a configuration of the display device 20 according to an embodiment of the present invention. FIG. 20 is a plan view showing a configuration of the display device 20 according to an embodiment of the present invention. In addition, the cross-sectional view of FIG. 18 is a cross-sectional view for explaining a layer structure of the display device 20 including the semiconductor device 10, and in practice, the pixel circuit is arranged in the image display region. In particular, in the pixel circuit in FIG. 18, a peripheral portion of the contact hole in the pixel region is shown at the center, and only a part of a transmission region (opening region) contributing to the display is shown. In FIG. 18, the liquid crystal layer and the counter substrate are not shown. FIG. 18 to FIG. 20 show an FFS (Fringe Field Switching) type liquid crystal display device, but may be an IPS (In Plane Switching) type liquid crystal display device.

Since the configuration of the semiconductor device 10 included in the display device 20 in FIG. 18 is substantially the same as the configuration of the semiconductor device 10 shown in FIG. 1, a point different from the semiconductor device 10 shown in FIG. 1 will be described.

As shown in FIG. 18 and FIG. 19, the display device 20 includes the semiconductor device 10. In FIG. 19, a layout of the semiconductor device 10 is different from the layout of the semiconductor device 10 shown in FIG. 2. As shown in FIG. 19, the gate wiring GL overlaps the light-blocking layer LS and extends in the first direction, and the oxide semiconductor layer OS is arranged along the second direction D2 so as to intersect the light-blocking layer LS and the gate wiring GL. In the gate wiring GL, a region overlapping the oxide semiconductor layer OS functions as a gate electrode. The wiring W1 is arranged so as to intersect the light-blocking layers LS and the gate wiring GL. The transparent conductive layer ZTCO is also arranged along the second direction D2 so as to overlap the oxide semiconductive layer OS. In addition, the fifth insulating layer IL5 is provided with a contact hole PCON for connecting the transparent conductive layer PTCO, which will be described later, to the transparent conductive layer ZTCO. The transparent conductive layer PTCO is in contact with the drain region DA in the contact region CON1 that does not overlap the gate line GL and the wiring W1 in a plan view. In a plan view, the contact region CON1 is included in the image display region of the pixel.

As shown in FIG. 18 and FIG. 20, in addition to the semiconductor device 10, the display device 20 further includes a sixth insulating layer IL6, the transparent conductive layer PTCO, a seventh insulating layer IL7, a common auxiliary electrode CMTL, the transparent conductive layer CTCO, and a spacer SP.

As shown in FIG. 18, the sixth insulating layer IL6 arranged on the fifth insulating layer IL5 alleviates steps formed by the structural member arranged below the sixth insulating layer IL6. The sixth insulating layer IL6 may be referred to as a planarization film.

The transparent conductive layer PTCO is arranged on the sixth insulating layer IL6. The transparent conductive layer PTCO is also referred to as a pixel electrode. The transparent conductive layer PTCO is connected to the transparent conductive layer ZTCO via contact holes PCON provided in the fifth insulating layer IL5 and the sixth insulating layer IL6. A region where the transparent conductive layer ZTCO and the transparent conductive layer PTCO are in contact with each other is referred to as a contact region CON2. In a plan view, the contact regions CON2 overlap the gate electrode GE.

The seventh insulating layer IL7 is arranged on the transparent conductive layer PTCO. The seventh insulating layer IL7 functions as a dielectric for forming capacitance. Therefore, a thickness of the seventh insulating layer IL7 may be smaller than the thickness of the fifth insulating layer IL5. The common auxiliary electrode CMTL and the transparent conductive layer CTCO are arranged on the seventh insulating layer IL7. As will be described later, the common auxiliary electrode CMTL and the transparent conductive layer CTCO have different planar patterns. The common auxiliary electrode CMTL is a metal layer. The transparent conductive layer CTCO is also referred to as a common electrode. An electric resistance of the common auxiliary electrode CMTL is lower than an electric resistance of the transparent conductive layer CTCO. In addition, the common auxiliary electrode CMTL also functions as a light-blocking layer. For example, the common auxiliary electrode CMTL blocks light from neighboring pixels, thereby suppressing occurrence of color mixing. The spacer SP is arranged on the transparent conductive layer CTCO.

The common auxiliary electrode CMTL is arranged in a grid pattern. The common auxiliary electrode CMTL is arranged so as to cross the contact hole PCON in the first direction D1, and is arranged so as to overlap the wiring W1 in the second direction D2. The transparent conductive layer CTCO is arranged on the common auxiliary electrode CMTL so as to cover the entire image display region. The transparent conductive layer CTCO is provided with a slit pattern in a region overlapping the transparent conductive layer PTCO. The slit pattern also overlaps the transparent conductive layer PTCO.

The spacer SP is provided for some of the pixels. For example, the spacer SP may be provided for any one of the red pixel R, the green pixel G, and the blue pixel B. However, the spacer SP may be provided in all the pixels. A height of the spacer SP is half a height of a cell gap. The spacer is also arranged on the counter substrate, and the spacer of the counter substrate and the spacer SP overlap each other in a plan view. In addition, a configuration in which the height of the spacer SP corresponds to the cell gap may also be applied. Further, as shown in FIG. 18, although the spacer protrudes toward the counter substrate while being filled in the contact hole PCON, it is also possible to adopt a configuration in which the contact hole is only filled with a filler.

### [2.5. Method for Manufacturing Display Device 20]

A method for manufacturing the display device 20 according to an embodiment of the present invention will be described. Since steps up to a step of forming the fifth insulating layer IL5 of the semiconductor device 10 in the manufacturing process of the display device 20 are the same as the steps described in the previous embodiment, detailed descriptions thereof will be omitted.

In the manufacturing process of the display device 20, after the fifth insulating layer IL5 is formed, the contact hole PCON is formed so as to expose part of the transparent conductive layer ZTCO. The contact hole PCON is formed in a region overlapping the gate line GL (see FIG. 18 and FIG. 19).

Next, the sixth insulating layer IL6 is formed on the fifth insulating layer IL5 (see FIG. 18 and FIG. 20). The sixth insulating layer IL6 is formed by applying and baking an organic insulating material. An organic resin such as a polyimide resin, an acrylic resin, an epoxy resin, a silicone resin, a fluorine resin, a siloxane resin, or the like is used as the organic insulating material. Thereafter, part of the fifth insulating layer is exposed and removed to form the contact hole PCON exposing the transparent conductive layer ZTCO.

Next, the transparent conductive layer PTCO is formed on the sixth insulating layer IL6 (see FIG. 18 and FIG. 20). The transparent conductive layer PTCO is connected to the transparent conductive layer ZTCO via the contact hole PCON. For the film formation method and the transparent conductive material of the transparent conductive layer PTCO film formation, refer to the explanation of the transparent conductive layer ZTCO.

Next, the seventh insulating layer IL7 is formed on the transparent conductive layer PTCO (see FIG. 18). For the film formation method and the insulating material of the seventh insulating layer IL7, refer to the description of the first insulating layer IL1. In the present embodiment, the seventh insulating layer IL7 is formed using silicon nitride. A thickness of the seventh insulating layer IL7 is smaller than the thickness of the fifth insulating layer IL5.

Next, the common auxiliary electrode CMTL is formed on the seventh insulating layer IL7 (see FIG. 18 and FIG. 20). For the film formation method and conductive material of the common auxiliary electrode CMTL, refer to the explanation of the light-blocking layer LS. The common auxiliary electrode CMTL is formed in a grid pattern so as to overlap the gate electrode GE and the wiring W1.

Next, the transparent conductive layer CTCO is formed on the seventh insulating layer IL7 and the common auxiliary electrode CMTL. For the film formation method and the transparent conductive material of the transparent conductive layer CTCO, refer to the description of the transparent conductive layer ZTCO.

Next, the spacer SP is formed on the transparent conductive layer CTCO (see FIG. 18). The spacer SP is formed in the contact hole PCON. Finally, the array substrate manufactured as described above and the counter substrate on which the color filter and the spacer are formed may be bonded to each other via a sealing material and a liquid crystal layer.

Through the above steps, the display device 20 according to an embodiment of the present invention can be manufactured.

The display device 20 according to an embodiment of the present invention is manufactured using the semiconductor device 10. In the semiconductor device 10, the fifth insulating layer IL5 including silicon nitride is provided. The fifth insulating layer IL5 including silicon nitride has a thickness of 30 nm or more and 700 nm or less. Therefore, the fifth insulating layer IL5 not only has a function of supplying hydrogen to the oxide semiconductor layer OS, but also has a function of blocking hydrogen contained in the sixth insulating layer IL6. Accordingly, in the manufacturing process of the display device 20, it is possible to prevent the hydrogen contained in the sixth insulating layer IL6 from being supplied to the oxide semiconductor layer OS via the fifth insulating layer IL5 and the transparent conductive layer ZTCO. As a result, it is possible to suppress the diffusion of hydrogen into the channel region CH, and it is easy to control the electrical properties of the transistor. Furthermore, variations in the amount of hydrogen supplied to the plurality of oxide semiconductor layers in the substrate surface can be suppressed. As a result, variations in the electrical characteristics of the transistor can be suppressed, and display unevenness in the image display region can be reduced. By including the semiconductor device 10, the display device 20 can improve display quality and reliability.

### [2.6. Modification 4]

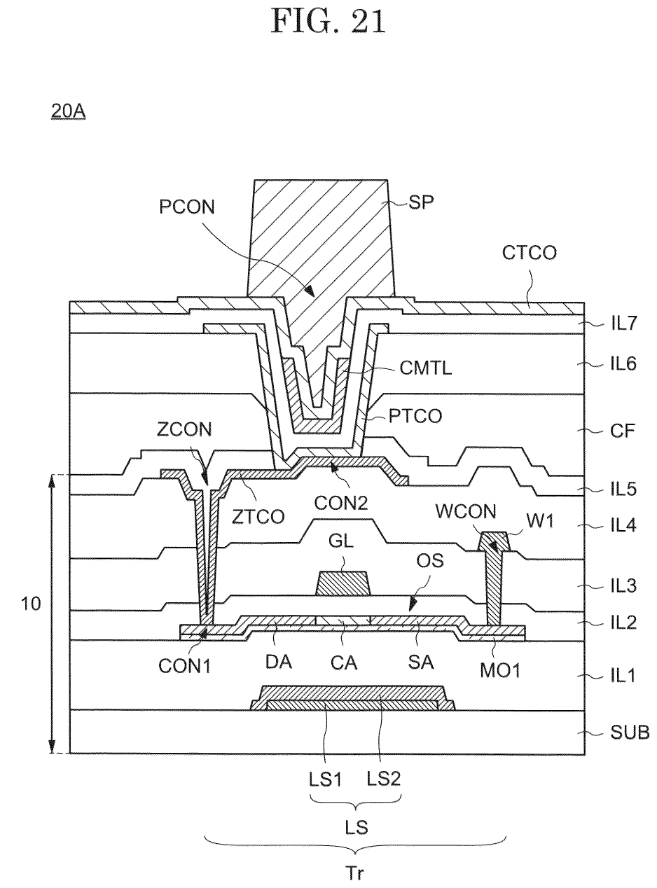

Next, the display device 20A partially differing from the display device 20 shown in FIG. 18 will be described referring to FIG. 21. In the display device 20A shown in FIG. 21, a color filter CF is arranged between the fifth insulating layer IL5 and the sixth insulating layer IL6.

In a liquid crystal display device, in the case where a color filter is arranged on a counter substrate, misalignment may occur when the array substrate on which a transistor or the like is formed and the counter substrate are bonded to each other. In a high-definition liquid crystal display device used for a VR or the like, a display of the display device is deteriorated due to a slight positional deviation between pixels of the array substrate and the color filters of the counter substrate. Therefore, by forming the color filter CF between the fifth insulating layer IL5 and the sixth insulating layer IL6, it is possible to suppress the positional deviation between the array substrate and the color filter at the time of bonding the array substrate and the counter substrate.

Since the color filter CF is also formed of an organic resin, it contains water. In the manufacturing process of the display device 20, it is possible to prevent moisture contained in the color filter CF and moisture contained in the sixth insulating layer IL6 from being supplied to the oxide semiconductor layer OS via the fifth insulating layer IL5 and the transparent conductive layer ZTCO. As a result, it is possible to prevent moisture from diffusing into the channel region CH, and thus it is easy to control the electric properties of the transistor. Furthermore, variations in the amount of hydrogen supplied to the plurality of oxide semiconductor layers in the substrate surface can be suppressed. As a result, it is possible to prevent variations in the electrical characteristics of the transistor from occurring. By including the semiconductor device 10, the display device 20 can improve display quality and reliability.

In a high-definition liquid crystal display device, the area of the contact regions CON1 of the oxide semiconductor layer OS and the transparent conductive layer ZTCO becomes smaller. Therefore, if the contact resistance between the oxide semiconductor layer OS and the transparent conductive layer ZTCO increases, the effects of the contact resistance on the display quality of the display device increases. In the display device 20, the contact resistance between the oxide semiconductor layer OS and the transparent conductive layer ZTCO can be sufficiently reduced, so that the display of the display device can be improved. In addition, in the case where the plurality of oxide semiconductor layers and a plurality of transparent conductive layers in the substrate surface are connected to each other, in-plane variations in the contact resistance can be reduced.

Although not shown, in the display device 20 described above, a configuration in which the color filter CF is arranged between the fifth insulating layer IL5 and the sixth insulating layer IL6 may be applied. Further, in the present embodiment, although the display devices 20 and 20A including the semiconductor device 10 have been described, the display devices 20 and 20A may also be appropriately applied to the semiconductor devices 10A and 10B.

### EXAMPLES

### Example 1

In this embodiment, variation in a resistance value of contact resistance before and after formation of the fifth insulating layer IL5 is evaluated in the semiconductor device 30. In addition, a difference in the resistance value of the contact resistor caused by the difference in the configuration and the film formation conditions of the fifth insulating layer IL5 will be described.

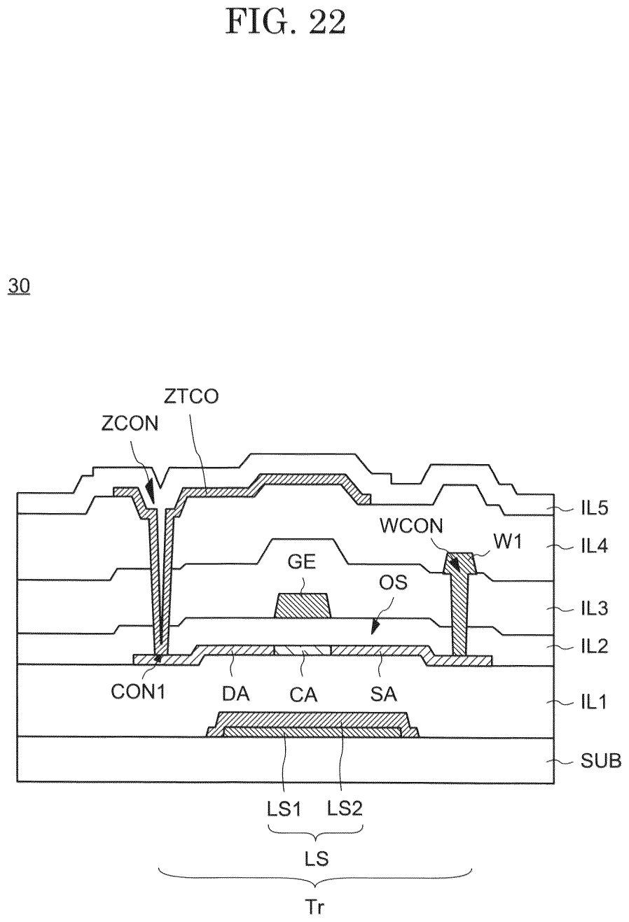

The configuration of the semiconductor device 30 formed in this embodiment will be described with reference to FIG. 22. In FIG. 22, configurations from the substrate SUB to the transparent conductive layer ZTCO are listed below.

### (Configuration of Semiconductor Device 30)

The first insulating layer IL1: a silicon nitride layer and a silicon oxide layer
Oxide semiconductor layer OS: IGZO
Second insulating layer IL2: Silicon oxide layer
Gate electrode GE: Molybdenum tungsten layer
Third insulating layer IL3: silicon nitride layer, silicon oxide layer
Wiring W1: lamination of titanium, aluminum, titanium
Fourth insulating layer IL4: silicon nitride layer
Transparent conductive layer ZTCO: ITO layer

The contact resistance was measured on the substrate SUB after forming from the light-blocking layer LS to the transparent conductive layer ZTCO. The contact resistance was measured using a test pattern (TEG) for measuring the contact resistance arranged on the substrate of the semiconductor device 30. Measurement points are 42 points in the substrate surface.

### (Condition A)

Next, as the fifth insulating layer IL5, a silicon nitride layer was formed as a single-layer structure of 90 nm. A deposition temperature of the silicon nitride layer was 250° C. or lower, and in this example, was 200° C. The contact resistance was then measured using the TEG described above.

Next, the fifth insulating layer IL5 formed under conditions other than the condition A will be described referring to the conditions B to G. In addition, the conditions B to G are the same as the condition A in the step of forming from the light-blocking layer LS to the transparent conductive layer ZTCO on the substrate SUB. In addition, for each of the conditions B to G, the contact resistance was measured after forming from the light-blocking layer LS to the transparent conductive layer ZTCO on the substrate SUB in the same manner as the condition A.

### (Condition B)

A silicon nitride layer was formed as a single-layer structure of 300 nm as the fifth insulating layer IL5. In the condition B, a silicon nitride layer was formed in the same manner as the condition A except that film thicknesses were different.

### (Condition C)

A silicon nitride layer was formed as a single-layer structure of 90 nm as the fifth insulating layer IL5. A deposition temperature of the silicon nitride layer was 250° C. or lower, and in this example, was 200° C. In the condition C, a film was formed under a condition in which an amount of hydrogen was reduced as compared with the condition A by adjusting pressure and a gas ratio.

### (Condition D)

A silicon nitride layer was formed in a single-layer structure of 300 nm as the fifth insulating layer IL5. In the condition D, a silicon nitride layer was formed in the same manner as in the condition C except that film thicknesses were different.

### (Condition E)

A silicon oxide layer was formed of 50 nm and a silicon nitride layer was formed of 300 nm as the fifth insulating layer. Film formation temperatures of the silicon oxide layer and the silicon nitride layer were higher than the film formation conditions in the conditions A to D, and were 400° C. or lower, and 350° C. in this example.

### (Condition F)

A silicon oxide layer was formed of 50 nm and a silicon nitride layer was formed of 400 nm as the fifth insulating layer. In the condition F, the silicon oxide layer and the silicon nitride layer were formed in the same manner as in the condition E except that a thickness of the silicon nitride layer was different.

### (Condition G)

A silicon oxide layer was formed of 50 nm and a silicon nitride layer was formed of 300 nm as the fifth insulating layer. The film-forming temperature of the silicon oxide layer and the silicon nitride layer was 400° C. or lower, and in this example, 350° C. In the condition G, the silicon oxide layer was formed under a condition in which an amount of hydrogen was reduced as compared with the condition E and the condition F by adjusting pressure and a gas ratio.

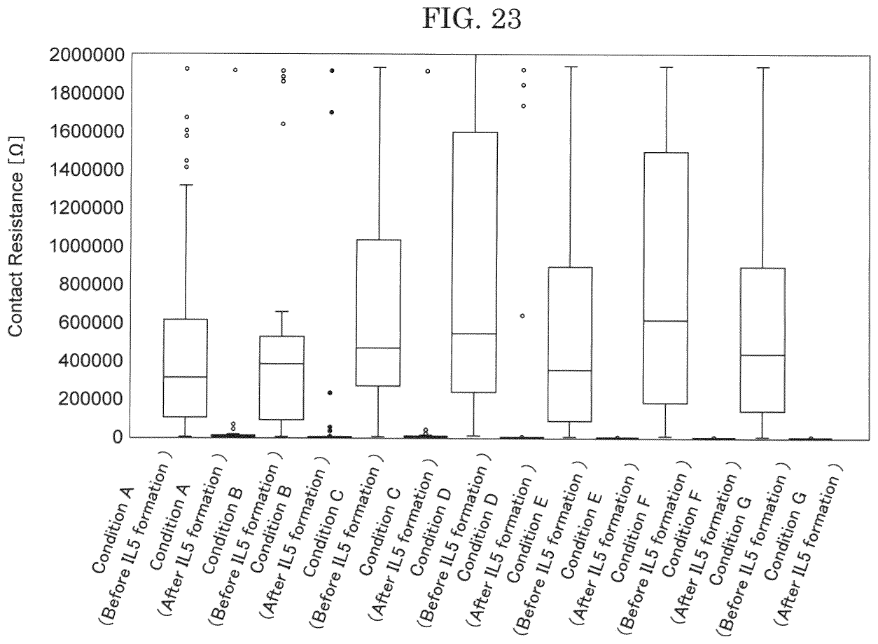

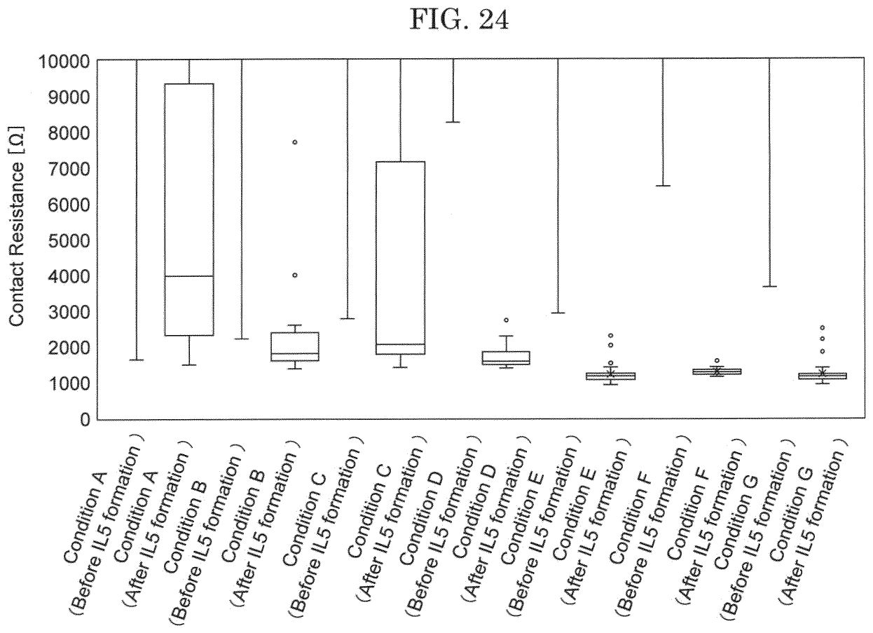

FIG. 23 and FIG. 24 are diagrams summarizing resistance values of the contact resistances before and after forming the fifth insulating layer IL5 in the conditions A to G. FIG. 24 is an enlarged view of a portion of the result shown in FIG. 23. In addition, table 1 summarizes the mean values of the contact resistances before and after the formation of the fifth insulating layer IL5 in the conditions A to G.

TABLE 1

| | Condition A | Condition B | Condition C | Condition D | Condition E | Condition F | Condition G |
|---|---|---|---|---|---|---|---|
| | (Ω) | (Ω) | (Ω) | (Ω) | (Ω) | (Ω) | (Ω) |
| After ZTCO | 310922 | 382668 | 466696 | 544429 | 353467 | 615351 | 437713 |
| film formation | | | | | | | |
| After IL5 | 3979.44 | 1799.43 | 2050.61 | 1577.8 | 1162.13 | 1272.26 | 1148.21 |
| film formation | | | | | | | |

As shown in FIG. 24, the contact resistance is reduced after the fifth insulating layer IL5 is formed. In the case where the silicon nitride layer is formed as a single layer, it was shown that the contact resistance is lower under conditions B and D, in which the film thickness is thicker, than under conditions A and C, in which the film thickness is thinner. In addition, it was shown that the contact resistance is lower in the condition D in which the amount of hydrogen is larger than in the condition B. In addition, the conditions E to G, which are formed by stacking the silicon oxide layer and the silicon nitride layer, indicate that the contact resistance is lower than the conditions A to D, which are formed by forming the silicon nitride layer as a single layer.

### Example 2

In the present embodiment, the unevenness of the silicon nitride layer is observed by a SEM in the case where a single-layer silicon nitride layer is formed at a high temperature and in the case where a single-layer silicon nitride layer is formed at a low temperature.

### Comparative Example H

A single-layer silicon nitride layer formed at a high temperature as the fifth insulating layer IL5 will be described. A step of forming the light-blocking layer LS to the transparent conductive layer ZTCO is the same as the condition A. Silicon nitride layers were formed in a film thickness of 90 nm.

### Example I

In the case where a single-layer silicon nitride layer is formed as the fifth insulating layer IL5 at a low temperature is the same as in the case of condition A, and thus a detailed explanation thereof is omitted. The silicon nitride layers were formed in the film thickness of 90 nm.

In the comparative example H, the silicon nitride layer was formed at a high temperature, so that the ITO film was reduced, resulting in irregularities on the ITO film. Therefore, unevenness also occurred on a surface of the silicon nitride layer. In contrast, in the example I, since the silicon nitride layer was formed at a low temperature, no irregularities were formed on the ITO film. Therefore, a surface of the silicon nitride layer was smooth.

As described above, it was confirmed that reduction of the ITO film was suppressed by forming a silicon nitride layer on the ITO film at a low temperature.

Each of the embodiments described above of the present invention can be implemented in any suitable combination as long as they are not mutually contradictory. Further, based on the semiconductor device and display device of each embodiment, those skilled in the art may add, delete, or modify the design of components as appropriate, or add, omit, or modify processes as appropriate, as long as they comply with the gist of the present invention.

It is to be understood that the present invention provides other operational effects that are different from the operational effects provided by the aspects of the embodiments described above, and those that are obvious from the description of the present specification or that can be easily predicted by a person skilled in the art.

What is claimed is:

1. A semiconductor device comprising:
an oxide semiconductor layer;
a gate electrode opposed to the oxide semiconductor layer;
a gate insulating layer between the oxide semiconductor layer and the gate electrode;
a first conductive layer connected to the oxide semiconductor layer;
a first transparent conductive layer arranged on a layer above the first conductive layer and connected to the oxide semiconductor layer; and
a first insulating layer containing silicon nitride arranged on and in contact with the oxide semiconductor layer.

2. The semiconductor device according to claim 1, wherein
a film thickness of the first insulating layer is 30 nm or more and 700 nm or less.

3. The semiconductor device according to claim 2, wherein
the first insulating layer is a silicon nitride layer.

4. The semiconductor device according to claim 2, wherein
the first insulating layer includes a silicon oxide layer and a silicon nitride layer arranged on the silicon oxide layer, and
a thickness of the silicon oxide layer is smaller than a thickness of the silicon nitride layer.

5. The semiconductor device according to claim 4, wherein
a thickness of the silicon nitride layer is 30 nm or more and 70 nm or less.

6. The semiconductor device according to claim 1, further comprising
a metal oxide layer having aluminum as a main component and being in contact with the oxide semiconductor layer.

7. A display device comprising the semiconductor device according to claim 1 further comprising
an organic resin layer arranged in contact with the first insulating layer.

8. The display device according to claim 7, further comprising
a second transparent conductive layer arranged on the organic resin layer and connected to the first transparent conductive layer through a contact hole arranged in the organic resin layer.

9. The display device according to claim 8, further comprising
a second insulating layer containing silicon nitride arranged on the second transparent conductive layer,
wherein a film thickness of the second insulating layer is smaller than a film thickness of the first insulating layer.

10. A method for manufacturing a semiconductor device, the method comprising steps of:
forming an oxide semiconductor layer;
forming a gate insulating layer on the oxide semiconductor layer;
forming a gate electrode on the gate insulating layer;
forming a first conductive layer in contact with the oxide semiconductor layer above the gate electrode;
forming a first transparent conductive layer in contact with the oxide semiconductor layer above the first conductive layer; and
forming a first insulating layer containing silicon nitride in contact with the first transparent conductive layer.

11. The method according to claim 10, wherein
a film thickness of the first insulating layer is 30 nm or more and 700 nm or less.

12. The method according to claim 10, further comprising
forming a silicon nitride layer as the first insulating layer,
wherein the silicon nitride layer is formed at 150° C. or higher and 250° C. or lower.

13. The method according to claim 10, further comprising
forming a silicon oxide layer as the first insulating layer and a silicon nitride layer on the silicon oxide layer,
wherein the silicon oxide layer and the silicon nitride layer are formed at 150° C. or higher and 400° C. or lower.

14. The method according to claim 13, wherein
a film thickness of the silicon nitride layer is 30 nm or more and 500 nm or less.

15. The method according to claim 10, further comprising
forming a metal oxide layer having aluminum as a main component before forming the oxide semiconductor layer.

16. A method for manufacturing a display device, the method comprising steps of:
forming the semiconductor device according to claim 10; and
forming an organic resin layer in contact with the first insulating layer after forming the first insulating layer.

17. The method according to claim 16, further comprising
forming a second transparent conductive layer on the organic resin layer and connecting the second transparent conductive layer to the first transparent conductive layer via one or more contact holes formed in the organic resin layer.

18. The method according to claim 17, further comprising
forming a second insulating layer containing silicon nitride on the second transparent conductive layer,
wherein a film thickness of the second insulating layer is smaller than a film thickness of the first insulating layer.
